(19) United States
(12) Patent Application Publication
(10) Pub. No.: US 2006/0017154 A1
(43) Pub. Date: Jan. 26, 2006

(54) Semiconductor device and method for manufacturing same

(76) Inventors: Toshimasa Eguchi, Tokyo (JP); Kazushige Takechi, Tokyo (JP)

Correspondence Address: SMITH, GAMBRELL & RUSSELL, LLP, 1230 PEACHTREE STREET, N.E., SUITE 3100, PROMENADE II, ATLANTA, GA, 30309-3592, US

(21) Appl. No.: 11/186,696

(22) Filed: Jul. 21, 2005

(30) Foreign Application Priority Data
Jul. 26, 2004 (JP) P2004-217961

(51) Int. Cl. H01L 23/12; H01L 21/58

(52) U.S. Cl. 257/701; 438/118; 438/459

(57) ABSTRACT

A method to provide an improved production yield of electronic devices. A thin film device 41 is manufactured by the following method. Semiconductor elements 11 are formed on the substrate 10. Then, a protective film is adhered onto the upper portions of the semiconductor elements 11 using an adhesive agent. Then, the substrate 10 is removed along the thickness direction from the surface thereof opposite to the surface having the semiconductor elements 11 provided thereon. Subsequently, a film 16 is adhered onto the surface of the removal-processed substrate 10. Subsequently, the protective film is removed. The obtained thin film device 41 is heat-treated.

This application is based on Japanese patent application NO. 2004-217961, contents of which are incorporated hereinto by reference.

### BACKGROUND OF THE INVENTION

1. Field of the Invention

The present invention relates to an electronic device and a method for manufacturing thereof.

2. Related Art

In recent years, developments of flexible liquid crystal display devices employing resin substrates are proceeded, aiming at presenting thin film transistor liquid crystal display devices that have reduced weight and are resistant to breaking. As an implementation thereof, a method for forming a device has been developed, which involves transferring or copying a pattern of a thin film transistor (TFT) array, that is once formed on a glass substrate, on a resin substrate (Akihiko Asano and Tomoatsu Kinoshita, entitled “Low-Temperature Polycrystalline-Silicon TFT Color LCD Panel Made of Plastic Substrates”, Society for Information Display 2002, International Symposium Digest of Technical Papers (USA), May, 2002, pp. 1196 to 1199).

According to Akihiko Asano et al., a method for manufacturing a flexible thin film transistor substrate is employed, in which the glass substrate having the thin film transistor array formed thereon is wet-etched from the back surface side thereof with a hydrofluoric acid-containing solution to completely remove the entire glass substrate, and a resin substrate is adhered to the etched surface to form a flexible thin film transistor substrate. Such conventional process will be described in reference to FIG. 15A, FIG. 15B, FIG. 16C and FIG. 16D.

First, a protective film 12 is adhered via an adhesive agent layer 33 on entire surface of a glass substrate 32 having an etch stop 30 and a thin film transistor array 31 formed thereon (FIG. 15A). Next, the glass substrate is completely etched to be removed from the back surface side thereof employing a hydrofluoric acid-containing etchant 34, and the etching process is stopped at the etch stop 30 (FIG. 15B). Subsequently, a resin substrate 35 is adhered onto the etched surface via an adhesive agent layer 33 (FIG. 16C). Then, the protective film 12 is stripped to complete a device having a transferred pattern on the resin substrate 35 (FIG. 16D).

It is described in Akihiko Asano et al. that the transfer can be achieved without considerably changing the characteristics of the TFT by employing this procedure.

### SUMMARY OF THE INVENTION

However, the present inventors conducted the transfer of a pattern of a thin film device by employing the above-described conventional method, and found that the production yield on the order of the prospective level was not able to be obtained in reality. Therefore, the present inventors have earnestly examined the possible cause thereof, and the following scientific knowledges have been found as the results thereof.

In the conventional transferred device, relatively larger warpage or bending is occurred in the device substrate, when a heat treatment process at a temperature of equal to or higher than 70 degree C. is conducted after the transfer. For example, when the thin film transistor-transferred device (FIG. 17A) having a size of 300 mm×350 mm manufactured by the process illustrated in FIG. 15A, FIG. 15B, FIG. 16C and FIG. 16D is heat-treated at a temperature of 80 degree C., an amount of warpage is 60 mm as shown in FIG. 17B, and the production yield in the handling or cutting thereafter is reduced. Here, an amount of warpage is defined as a difference in the height between the lowest portion and the highest portion of the resin substrate 35 in any region of the transferred device when a normal vector extending from the surface of the transferred device toward a surface opposite to the resin substrate 35 is oriented toward a horizontal plane or is oriented toward above from the horizontal plane in the case that the obtained transferred device is disposed on a flat surface.

Further, the amount of warpage was increased when a polyimide film was applied as an oriented film and thereafter was annealed at a temperature of 180 degree C., in order to utilize the finished thin film transistor transferred device for a liquid crystal display. As a result, the production yield was decreased in the later cutting process and/or in the adhering process with other substrate.

Therefore, in order to improve the production yield and improve the reliability, a design based on a new concept for preventing the warpage in the heating process thereafter is required.

The present invention has been conceived in view of the foregoing situation, and an object of the present invention is to provide a technology that is capable of improving a production yield for electronic devices.

In the case of a thin device that has a semiconductor element having a thickness of 200 μm or less, it is general to employ a substrate having a dimension of 100 mm or larger on one side, based on a consideration on the productivity and/or the mass productivity. Excessively smaller dimension of the substrate leads to a decrease in the productivity, since sufficient number of electronic devices per one piece of substrate cannot be obtained.

However, as stated above, when the transferred electronic device is manufactured by employing the substrate having a dimension of 100 mm or larger on one side, and thereafter, the obtained electronic device is heat-treated at a temperature of 70 degree C. or higher, for example, the electronic device is warped or bended by a thermal expansion and/or a shrinkage of the resin substrate and/or the adhesion layer. Although a heat treatment process is required for obtaining a characteristic stability of the formed electronic device after any of processes, the electronic device is warped due to the heat treatment process. In particular, in the case of larger-scale transferred device having a dimension of 300 mm or larger on one side, the amount of warpage is, for example, 50 mm or larger, and therefore the handling thereof in the subsequent process is difficult. Further, larger amount of warpage may lead to an increase of the warpage of the segmented device cut off from the larger-scale transferred device to an indispensable level.

Therefore, the present inventors have earnestly continued further researches on finding the possible cause of the warpage in order to obtain an improvement in the production yield of the thinner electronic device including the semiconductor element having a thickness of 200 μm or less, and the following scientific knowledges have been newly found.

It has been found in the case of transferring the electronic device formed on the glass substrate that a material, which is insoluble to a hydrofluoric acid-containing solution, precipitates on the surface of the glass substrate, when the glass substrate is etched with the hydrofluoric acid-containing solution. Such precipitation, in turn, obstructs the uniform etching. The etching non-uniformly proceeds to provide a variation of the thickness in the glass substrate, such that the warpage of the transferred device is increased in the portion having a thinner thickness, in particular, and thus this becomes a factor of obstructing the stable manufacture of a flat electronic device.

Further, such precipitates may be a possible cause of generating the microscopic unevenness on the etched surface, in addition to the possible cause of the fluctuation in the thickness of the glass substrate. Moreover, while an appropriate unevenness is effective for maintaining the adhesive strength with the adhesion layer, a presence of an excessive unevenness may cause a diffuse reflection of light, and may adversely affect the performances of the electronic device.

The present invention has been completed on the basis of the above-described new scientific knowledges.

According to one aspect of the present invention, there is provided an electronic device, comprising: a first base member; a semiconductor element, being provided on an element formation surface of the aforementioned first base member and having a thickness of equal to or smaller than 200 μm; and a second base member, being provided on a back surface of the aforementioned first base member, wherein an average roughness along a center line (Ra) of the aforementioned back surface of the aforementioned first base member is equal to or smaller than 3 μm.

According to the above-described aspect of the present invention, the electronic device exhibiting smaller warpage, which could hardly be obtained by the conventional method, can be obtained by setting Ra of the back surface of the first base member as 3 μm or smaller, as discussed later.

Here, the aforementioned average roughness along a center line (Ra) is determined by Japanese Industrial Standard (JIS) B0601, and can be measured by employing, for example, a profiler or a three-dimensional measuring apparatus. This can also be measured by employing a scanning electron microscope (SEM), an atomic force microscope (AFM) or the like.

Here, a configuration having an interposing layer between the first base member and the second base member may be employed. For example, in the electronic device according to the present invention, a configuration having an adhesive layer provided between the aforementioned second base member and the aforementioned first base member may be employed. Having such configuration, the first base member can be surely joined to the second base member. Thus, further reliable configuration can be provided to the electronic device.

The electronic device of the aspect of the present invention may further comprise an additional configuration, in which the aforementioned adhesive layer consists essentially of a UV curable resin. Having such configuration, the first base member can be surely joined to the second base member by irradiating light. Thus, the warpage of the electronic device can be more surely reduced.

The electronic device of the aspect of the present invention may further comprise an additional configuration, in which the aforementioned adhesive layer consists essentially of a thermosetting resin, and a curing shrinkage of the aforementioned adhesive layer may be equal to or less than 5%. Having such configuration, the warpage of the electronic device can be surely reduced to improve the production yield. Here, in this specification, the curing shrinkage is defined as a combination of a reaction shrinkage and a thermal shrinkage, and can be obtained by measuring specific gravities of the uncured resin and the cured resin pursuant to JIS A6024.

The electronic device of the aspect of the present invention may further comprise an additional configuration, in which the aforementioned second base member comprises one or more resin selected from a group consisting of polyimide, polyamide, and polyamide imide. Having such configuration, the second base member can have a reduced linear expansion coefficient. Therefore, the warpage of the electronic device can be further surely reduced.

The electronic device of the aspect of the present invention may further comprise an additional configuration, in which the aforementioned second base member contains a crosslinked resin material and an inorganic material. The adhesiveness for the first base member can be improved by employing the crosslinked resin material. For example, the electronic device of the aspect of the present invention may further comprise a configuration, in which the aforementioned second base member contains an epoxy crosslinked resin or an acrylic crosslinked resin and a inorganic material.

The electronic device of the aspect of the present invention may further comprise an additional configuration, in which the aforementioned second base member comprises a material that is transparent to UV. Having such configuration, sufficient transparency can be ensured, even if the electronic device according to the present invention is an element, for which an optical transparency is required. In addition, in the case of having the photo-setting adhesive layer, the adhesion thereof can be additionally ensured. A material having an optical transmittance of equal to or higher than 40% at a wavelength of 365 nm is preferably employed for the material that is transparent to UV. Further, a material having an optical transmittance at a wave length of 400 nm of equal to or higher than 75% and an optical transmittance at a wave length of 550 nm of equal to or higher than 80% can be employed for the material that is transparent to UV, for example.

The electronic device of the aspect of the present invention may further comprise an additional configuration, in which the aforementioned second base member contains either one of aliphatic acrylate and alicyclic epoxy resin. For example, a polymer, which is obtainable by polymerizing an aliphatic acrylate containing multiple functional groups, may be employed.

The electronic device of the aspect of the present invention may further comprise an additional configuration, in which a linear expansion coefficient of the aforementioned second base member at a temperature of from 30 degree C. to 100 degree C. is equal to or lower than 30 ppm/degree C. Having such configuration, the generation of warpage in the electronic device can be further surely reduced. Here, in the present invention, the linear expansion coefficient of the second base member may be obtained pursuant to JIS K6911, by employing, for example, thermo mechanical analysis (TMA).

The electronic device of the aspect of the present invention may further comprise an additional configuration, in which the aforementioned first base member is a glass. Since the thin film device of the present invention comprises the back surface of a first base member having Ra of equal to or lower than 3 μm, the generation of the warpage can be restrained even if the first base member is a glass.

The electronic device of the aspect of the present invention may further comprise an additional configuration, in which the aforementioned first base member is presented as a thin film. Having such configuration, a flexibility of the electronic device can be improved.

The electronic device of the aspect of the present invention may further comprise an additional configuration, in which the aforementioned back surface of the aforementioned first base member is an etched surface. Alternatively, the aforementioned back surface of the aforementioned first base member of the electronic device of the aspect of the present invention may be a polished surface. Having such configuration, the electronic device can be configured to ensure further reduced generation of the warpage.

The electronic device of the aspect of the present invention may further comprise an additional configuration, in which a geometry of the aforementioned second base member is a film-shaped geometry. Having such configuration, a flexibility and a manufacturing stability of the electronic device can be improved.

The electronic device of the aspect of the present invention may further comprise an additional configuration, in which the aforementioned second base member is a flexible substrate. Having such configuration, the electronic device is flexible and resistant to breakage.

The electronic device of the aspect of the present invention may further comprise an additional configuration, in which said semiconductor device is manufactured by conducting a heat treatment process over a multiple-layered structure at a temperature of not lower than 70 degree C., said multiple-layered structure comprising at least said second base member and said semiconductor element, wherein the electronic device has an arbitrary geometry that is capable of masking a square having one side of 100 mm and the thickness of the semiconductor element is equal to or smaller than 200 μm, wherein said electronic device has a spatial relationship, in which, when said electronic device is placed on a flat surface without exerting any external force, a normal vector is oriented toward a horizontal plane or is oriented toward above from the horizontal plane, said normal vector extending from entire regions of said semiconductor element to a direction opposite to the direction toward the second base member, and wherein the highest point of the electronic device is equal to or lower than 50 mm-high from the surface of the flat surface.

Since the highest point of the electronic device is equal to or lower than 50 mm-high from the surface of the flat surface, reduced warpage is exhibited even though the device is manufactured by conducting the heat treatment process at a temperature of not lower than 70 degree C. Thus, the higher production yield and better manufacturing stability can be provided.

The electronic device of the aspect of the present invention may be manufactured by cutting a segmented device of an arbitrary geometry out from the aforementioned electronic device. Since the electronic device according to the present invention is manufactured by cutting a segmented device out from the device exhibiting smaller warpage, the generation of the warpage is restrained.

The electronic device of the aspect of the present invention may further comprise an additional configuration, in which the aforementioned semiconductor element is a thin film silicon transistor (TFT) element or a thin film diode (TFD) element, which is formed on a film consisting essentially of silicon oxide or silicon nitride. Having such configuration, a flexible thin film silicon device that exhibits reduced warpage and better production yield can be stably obtained.

The electronic device of the aspect of the present invention may further comprise an additional configuration, in which a thickness of the aforementioned film consisting essentially of silicon oxide or silicon nitride is within a range of from 20 nm to 200 μm. Having such configuration, the flexibility of the electronic device can be further improved.

The electronic device of the aspect of the present invention may further comprise an additional configuration, in which an average roughness along a center line (Ra) of a film surface on a side of the aforementioned film consisting essentially of silicon oxide or silicon nitride facing the aforementioned second base member is within a range of from 1 nm to 3 μm. Having such configuration, warpage occurred by the heat treatment process at a temperature of equal to or higher than 70 degree C. can be more surely inhibited.

The electronic device of the aspect of the present invention may further comprise an additional configuration, in which the aforementioned thin film silicon transistor element or the aforementioned thin film diode element is employed as an element for a display unit. Having such configuration, a flexible thin film element for display exhibiting better production yield can be stably obtained.

The electronic device of the aspect of the present invention may further comprise an additional configuration, in which the aforementioned semiconductor element is formed on a silicon wafer, a compound semiconductor wafer or a silicon on insulator (SOI) wafer. Having such configuration, reduced warpage and better production yield can be involved in the devices formed on these wafers.

According to one aspect of the present invention, there is provided a method for manufacturing an electronic device, comprising: forming a semiconductor element on a first base member; removing a portion of the aforementioned first base member from a surface opposite to a surface having the aforementioned semiconductor element provided thereon to reduce the thickness of the aforementioned first base member; adhering the second base member to the surface of the aforementioned first base member opposite to the surface having the aforementioned semiconductor element provided thereon to obtain the electronic device; and heating the aforementioned electronic device after the aforementioned adhering the second base member, wherein the aforementioned removing a portion of the aforementioned first base member to reduce the thickness thereof includes providing an average roughness along a center line (Ra) of the surface of the aforementioned first base member opposite to the surface having the aforementioned semiconductor element provided thereon to equal to or lower than 3 μm.

According to the above-described aspect of the present invention, the method for manufacturing an electronic device includes removing a portion of the aforementioned first base member to reduce the thickness thereof. Then, in such process, Ra in the surface of the first base member opposite to the surface having the semiconductor element provided thereon is selected to be equal to or lower than 3 μm. This can provide a reduced unevenness of the surface of the first base member. This, in turn, can provide a reduced fluctuation in the thickness of the first base member. Thus, generation of the warpage in the process of heating the electronic device can preferably be prevented. Moreover, the characteristics of the semiconductor element can be improved by the heating. Therefore, the electronic device having better characteristics can be stably manufactured at high production yield.

The method for manufacturing the electronic device according to the aspect of the present invention may further comprise an additional configuration, in which the aforementioned heating the electronic device includes heating the aforementioned electronic device to a temperature of equal to or higher than 70 degree C. In the conventional technology, generation of the warpage is considerably occurred when the process includes heating the electronic device at a temperature of not lower than 70 degree C. Since Ra of the surface of the first base member opposite to the surface having the semiconductor element provided thereon is selected to be equal to or lower than 3 μm in the method of the present invention, generation of the warpage can be surely inhibited even in such situation.

The method for manufacturing the electronic device according to the aspect of the present invention may further comprise an additional configuration, in which the aforementioned removing a portion of the aforementioned first base member to reduce the thickness thereof includes providing ultrasonic vibration to an etchant while maintaining a condition of the aforementioned etchant contacting with the aforementioned first base member. Having such configuration, when precipitates are created on the surface of the first base member during an etching process, the created precipitates can be removed by the ultrasonic vibration and the deposition thereof on the surface of the first base member can be prevented.

The method for manufacturing the electronic device according to the aspect of the present invention may further comprise an additional configuration, in which the aforementioned removing a portion of the aforementioned first base member to reduce the thickness thereof includes contacting the surface of the aforementioned first base member opposite to the surface having the aforementioned semiconductor element provided thereon with a flush flow of the aforementioned etchant. Having such configuration, when precipitates are created on the surface of the first base member during an etching process, the created precipitate can be removed by the flush flow of the etchant and the deposition thereof on the surface of the first base member can be prevented.

The method for manufacturing the electronic device according to the aspect of the present invention may further comprise an additional configuration, in which the aforementioned first base member is a glass, and the aforementioned etchant contains hydrofluoric acid. Having such configuration, etching of the first base member of the glass can be definitely achieved to reduce the thickness thereof. In addition, while precipitates are generally created during the etching process, the etching process in the method according to the present invention is conducted so that no precipitate is created on the surface of the glass, and therefore the unevenness in the etched surface can be reduced while providing the reduced thickness of the first base member composed of glass.

The method for manufacturing the electronic device according to the aspect of the present invention may further comprise an additional configuration, in which the aforementioned removing a portion of the aforementioned first base member to reduce the thickness thereof includes polishing the aforementioned first base member. Having such configuration, when a precipitate is created on the surface of the first base member during an etching process, the created precipitate can be removed by the flush flow of the etchant to avoid depositing thereof on the surface of the first base member.

The method for manufacturing the electronic device according to the aspect of the present invention may further comprise an additional configuration, in which the aforementioned adhering the second base member includes introducing an adhesion layer between the aforementioned first base member and the aforementioned second base member. Having such configuration, the first base member can be surely joined to the second base member. Thus, the highly reliable electronic device can be stably obtained.

The method for manufacturing the electronic device according to the aspect of the present invention may further comprise cleaning the aforementioned surface of the aforementioned first base member opposite to the surface having the aforementioned semiconductor element provided thereon or the surface of the aforementioned second base member, before the aforementioned adhering the second base member.

The method for manufacturing the electronic device according to the aspect of the present invention may further comprise activating the aforementioned surface of the aforementioned first base member opposite to the surface having the aforementioned semiconductor element provided thereon or the surface of the aforementioned second base member, before the aforementioned adhering the second base member.

Having such configuration, the adhesiveness between the first base member and the second base member can be improved. Thus, the electronic device exhibiting smaller warpage can be more stably obtained.

The method for manufacturing the electronic device according to the aspect of the present invention may further comprise providing a protective layer on the aforementioned semiconductor element, after the aforementioned forming the semiconductor element and before the aforementioned removing a portion of the aforementioned first base member to reduce the thickness thereof. The method for manufacturing the electronic device according to the aspect of the present invention may further comprise removing the aforementioned protective layer, after the aforementioned removing a portion of the aforementioned first base member to reduce the thickness thereof. Having such configuration, characteristics of the semiconductor element can be fully maintained. Thus, characteristics of the electronic device can be improved.

As have been described above, according to the present invention, a technology for providing an improved production yield of electronic devices can be achieved.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, schematically showing a configuration of a thin film device according to an embodiment of the present invention;

FIG. 2A to FIG. 2C are cross-sectional views of the thin film device, illustrating a procedure for manufacturing the thin film device shown in FIG. 1;

FIG. 3D to FIG. 3F are cross-sectional views of the thin film device, illustrating a procedure for manufacturing the thin film device shown in FIG. 1;

FIG. 4 is a cross-sectional view, schematically showing a configuration of a thin film device according to an embodiment of the present invention;

FIG. 5A to FIG. 5C are cross-sectional views of the thin film device, illustrating a procedure for manufacturing the thin film device shown in FIG. 4;

FIG. 6D and FIG. 6E are cross-sectional views of the thin film device, illustrating a procedure for manufacturing the thin film device shown in FIG. 4;

FIG. 7 is a cross-sectional view, schematically showing a configuration of a thin film device according to an embodiment of the present invention;

FIG. 8A to FIG. 8C are cross-sectional views of the thin film device, illustrating a procedure for manufacturing the thin film device shown in FIG. 7;

FIG. 9D and FIG. 9E are cross-sectional views of the thin film device, illustrating a procedure for manufacturing the thin film device shown in FIG. 7;

FIG. 10 is a photograph, showing an etched surface of a substrate according to the example of the present invention;

FIG. 11 is a photograph, showing an etched surface of a substrate according to the example of the present invention;

FIG. 12 is a graph, showing a relationship of Ra with the amount of warpage for the surface of the substrate according to the example of the present invention;

FIG. 13 is a cross-sectional view, schematically showing a configuration of a thin film device according to an example of the present invention;

FIG. 14 is a cross-sectional view, schematically showing a configuration of a thin film device according to an example of the present invention;

FIG. 15A and FIG. 15B are cross-sectional views of the thin film device, illustrating a procedure for manufacturing a conventional thin film device;

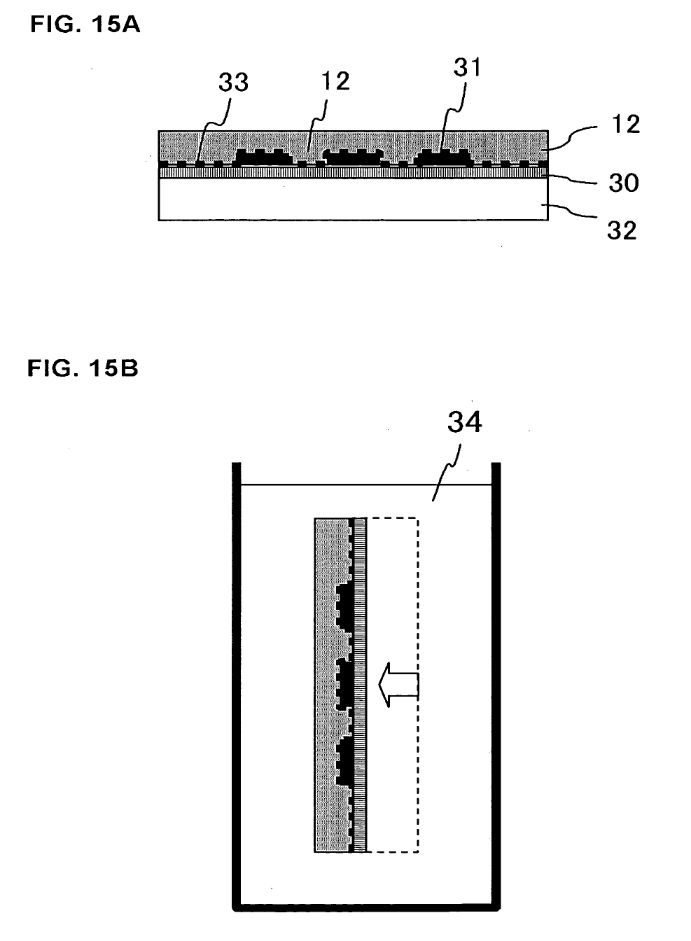

FIG. 16C and FIG. 16D are cross-sectional views of the thin film device, illustrating a procedure for manufacturing the conventional thin film device; and

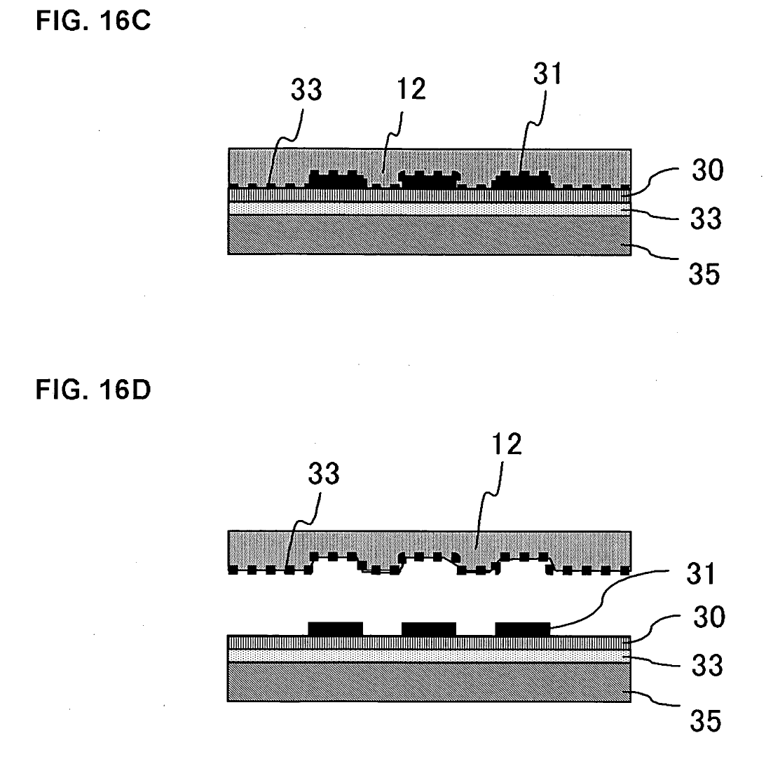

FIG. 17A and FIG. 17B are cross-sectional views, schematically showing a configuration and condition of the conventional thin film device.

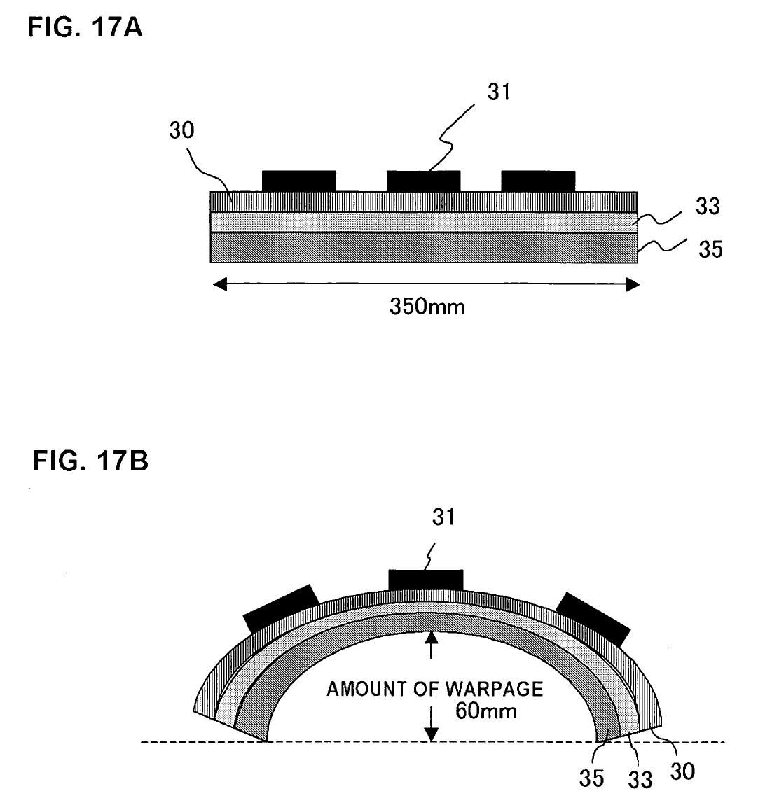

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Embodiments according to the present invention will be described as follows in further detail, in reference to the annexed figures. In all figures, identical numeral is assigned to an element commonly appeared in the figures, and the detailed description thereof will not be presented.

### First Embodiment

The present embodiment relates to a flexible integrated circuit device, in which an array of semiconductor elements is formed.

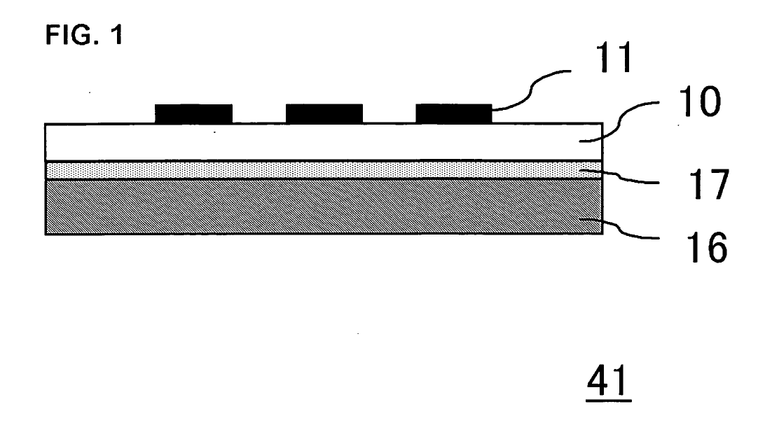

FIG. 1 is a diagram, showing a thin film device 41 according to the present embodiment. Thin film device 41 comprises a multiple-layered configuration that is formed of a film 16, an adhesive layer 17, a substrate 10 and semiconductor elements 11, which are layered in this sequence.

In the thin film device 41, a plurality of semiconductor elements 11 are provided on the surface of the substrate 10 to form an array-status. The semiconductor element 11 is appropriately selected according to an intended application of the thin film device 41, and may be, for example, a TFT such as a polysilicon TFT array, a thin film diode (TFD), metal wirings or the like.

The thickness of the semiconductor element 11 may be, for example, equal to or less than 200 μm, and preferably equal to or less than 100 μm. This can provide a device having a reduced thickness. While there is no particular limitation in the lower limit of thickness of the semiconductor element 11, the thickness may be, for example, equal to or larger than 1 μm. Having such condition, the manufacturing stability for the semiconductor element 11 can be improved.

The substrate 10 may be composed of an in insulating material, for example. For example, a substrate consisting essentially of silicon oxide or silicon nitride may be employed. More specifically, the substrate 10 may be a glass substrate of non-alkali glass, for example.

The dimension and geometry of the substrate 10 may be an arbitrary geometry having a dimension sufficient for masking a square having one side of 100 mm, for example. For example, a square having one side of 300 mm may be employed. Since the thin film device 41 has the configuration that provides inhibiting the exhibition of the warpage due to the heating, as discussed later, better manufacturing stability can be presented even if the size of the substrate 10 is larger, and thus a decrease of the production yield is restrained.

The thickness of the substrate 10 may be equal to or larger than 20 nm, for example, and preferably equal to or larger than 100 nm. Having such dimension, mechanical strength of the semiconductor element 11 can be ensured. On the other hand, the thickness of the substrate 10 may be equal to or smaller than 200 μm, for example, and preferably equal to or smaller than 100 μm. Having such dimension, flexibility of the substrate 10 can be fully ensured. Even if the substrate 10 is thinned to reduce the thickness thereof, generation of the warpage by heating can be preferably inhibited, since the average roughness along a center line Ra of the back surface is equal to or smaller than 3 μm.

In addition, a material, which exhibits an average roughness along a center line (Ra) of equal to or smaller than 3 μm, and preferably equal to or smaller than 1.5 μm for the unevenness in the surface of the side having the film 16 joined thereto, may be employed for the substrate 10. Having such condition, generation of the warpage by heating the thin film device 41 can be inhibited. Further, occurrence of a scattering of light by the uneven surface can be prevented to improve the optical transmittance of the substrate 10. Thus, the configuration can be preferably employed for the thin film device 41 that requires transparency for the substrate 10 such as a liquid crystal display unit. While there is no particular limitation in the lower limit of Ra for the relevant surface the substrate 10, Ra may be selected as equal to or larger than 1 nm, for example. Having such condition, better adhesiveness between the substrate 10 and the adhesive layer 17 can be ensured.

The semiconductor element layer composed of the substrate 10 and the semiconductor element 11 can be utilized as a driving element for a display unit such as liquid crystal display, organic electroluminescent (EL) display and the like, for example.

An organic resin material, for example, can be employed as the material of the film 16. Further, a configuration having a combination of an organic resin material and an inorganic material may also be employed. Further, a material having controlled optical characteristics is employed for the film 16, so that the film can preferably be utilized for the display unit of the liquid crystal display. Further, a metallic thin film such as copper foil, aluminum foil and the like is employed for the film 16, so that the film is suitable for integrated circuits.

More specifically, available organic resin materials may include, for example, polyimide, polyamide, polyamide imide and the like. The use of these materials may lead to a reduction of linear expansion coefficient of the film 16, due to their molecular structures. Thus, the use of these materials can provide an inhibition to the generation of the warpage caused by a difference in the linear expansion coefficient between the substrate 10 or the adhesive layer 17 and the film 16.

In addition, available organic resin materials may include crosslinked resins such as acrylic crosslinked resin such as aliphatic acrylate, epoxy crosslinked resin such as alicyclic epoxy resin and the like. The use of the crosslinked resin can fully ensures the strength of the film 16. In addition, an inorganic material may also be uniformly dispersed in the film 16.

Available inorganic materials may include, for example, silica (SiO₂), glass fiber and the like. Addition of the inorganic material into the film 16 can enhance the mechanical strength of the substrate 10.

The film 16 may be a material having transparency at a predetermined wave length. For example, the material for the film 16 may be a material having a optical transmittance of equal to or higher than 40% at a wave length of 365 nm. Further, a material having an optical transmittance at a wave length of 400 nm of equal to or higher than 75% and an optical transmittance at a wave length of 550 nm of equal to or higher than 80% can be employed as the material for the film 16, for example. Having such condition, better transparency at a predetermined wave length can be ensured, even if the thin film device 41 is an element, for which an optical transparency is required, such as display unit and the like.

Such materials may include, for example, resins such as polyethylene terephthalate, polyethylenenaphthalate, polybutylene terephthalate, polycarbonate, polysulfone, polyethersulfone, poly cycloolefin, copolymer containing cycloolefin, acrylic crosslinked resin, epoxy crosslinked resin, unsaturated polyester crosslinked resin and the like. In addition to these resins, an inorganic material such as silica, glass fiber and the like may also be included therein.

In addition, phase difference of the film 16 at a wave length of 550 nm may be adjusted to be equal to or less than 10 nm. Having such condition, the resultant film can is suitable for an application, in which a polarized transparency is required for the film 16, such as the application that the thin film device 41 is used for the liquid crystal display. Such materials may include, for example, the above-described transparent resin materials, or mixtures thereof with inorganic materials.

In addition, a material having a linear expansion coefficient at a temperature of from 30 degree C. to 100 degree C. of equal to or lower than 30 ppm/degree C. may be employed for the film 16. Having such condition, generation of the warpage caused by the heating can be reduced, even if the film is composed of a material having higher elastic modulus. Available materials may include, for example, materials containing a resin such as polyimide, aromatic polyamide and the like and an additional inorganic material.

Further, when the film 16 is composed of a resin, the available material thereof may be a material having a glass-transition temperature of equal to or higher than 200 degree C. Such configuration is preferable, since wider process condition for the heating process conducted in the manufacturing process such as process for forming the protective layer on the upper portion of the thin film device 41 or process for packaging of the thin film device 41 can be utilized. Available resin materials may include, for example, polyimide, polyamide imide, polyetherimide, polyethersulfone, epoxy crosslinked resin, acrylic crosslinked resin and the like.

Further, the adhesive layer 17 is provided to the thin film device 41, so that the junction between the substrate 10 and the film 16 can be further ensured.

The adhesive layer 17 may be composed of a material having a glass transition temperature of equal to or higher than 200 degree C., for example, and preferably equal to or higher than 240 degree C. Having such configuration, process condition for the heating process conducted in the manufacturing process such as process for forming on the upper portion of the thin film device 41 the protective layer that protects the semiconductor element 11 or process for packaging the thin film device 41 can be widely employed. Further, the upper limit of glass transition temperature can be appropriately selected depending on the adhesive method, and may be equal to or less than 300 degree C., for example.

Further, the adhesive layer 17 may be composed of a material having better transparency, similarly as the film 16. For example, an optical transmittance at a wave length 365 nm of the adhesive layer 17 may be equal to or higher than 40%. Further, an optical transmittance at a wave length 400 nm of the adhesive layer 17 may be equal to or higher than 75% and an optical transmittance at a wave length of 550 nm may be equal to or higher than 80%. Having such condition, sufficient transparency can be ensured, even if the thin film device 41 is an element, for which an optical transparency is required, such as display unit and the like.

In addition, phase difference of the adhesive layer 17 at a wave length of 550 nm may be adjusted to be equal to or less than 10 nm. Having such condition, the resultant film is suitable for an application, in which a polarized transparency is required for the adhesive layer 17, such as the application that the thin film device 41 is used for the liquid crystal display.

Available forms of the adhesive layer 17 may include, for example, a form obtainable by drying a thermoplastic resin containing a solvent after an adhesion to provide a hardened material, a form composed of a photo-setting resin, a form composed of a reactive-cured resin, a form composed of a thermosetting resin, a form composed of a hot melt adhesive, a form composed of a cohesive agent and the like. In addition, an adhesive having combined multiple performances of the above described available forms may also be employed. Available materials for the adhesive may include, for example, acrylic adhesive, epoxy adhesive, silicone adhesive and the like.

Among these available forms, the configuration of the adhesive layer 17 composed of a photo-setting resin is preferably employed, since such configuration can utilize a material that is curable at room temperature and has a glass transition temperature of equal to or higher than 200 degree C. Available photo-setting resin may include, for example, acrylic resin, epoxy resin and the like.

In addition, the form composed of a thermosetting resin provides greater possibility of having better adhesiveness with a material comprising silicon oxide and silicon nitride as a main component. Thus, these materials can be preferably employed depending on the material of the substrate 10 or the film 16. Available thermosetting resin may include, for example, epoxy resin, unsaturated polyester resin and the like.

Here, the material of adhesive layer 17 may be epoxy crosslinked resin, acrylic crosslinked resin, unsaturated polyester and the like. These materials may be employed singly or in combination of two or more.

Next, a method for manufacturing the thin film device 41 will be described. Thin film device 41 is obtained by sequentially conducting the following process steps of:
(i) forming semiconductor elements 11 on the substrate 10 to form a semiconductor element layer;
(ii) affixing a protective film 12 onto an upper portion of the semiconductor element layer via a cohesive agent 13;
(iii) removing the substrate 10 along the thickness direction from the surface thereof opposite to the surface having the semiconductor elements 11 provided thereon;
(iv) adhering a film 16 onto the surface, which is treated by the step of (iii);
(v) removing protective film 12; and
(vi) conducting a heat treatment at a temperature of equal to or higher than 70 degree C. over the obtained device. The process will be described as follows in reference to the drawings by every process step.

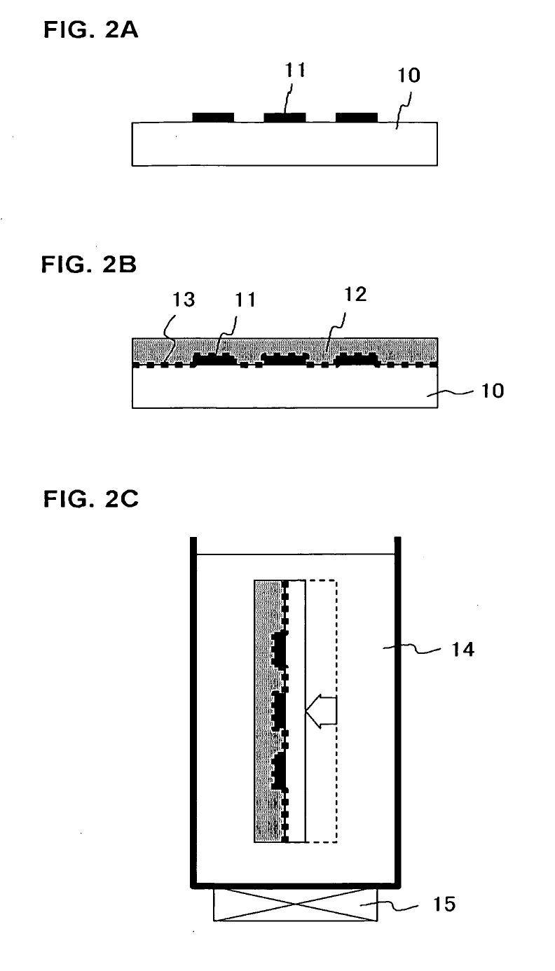

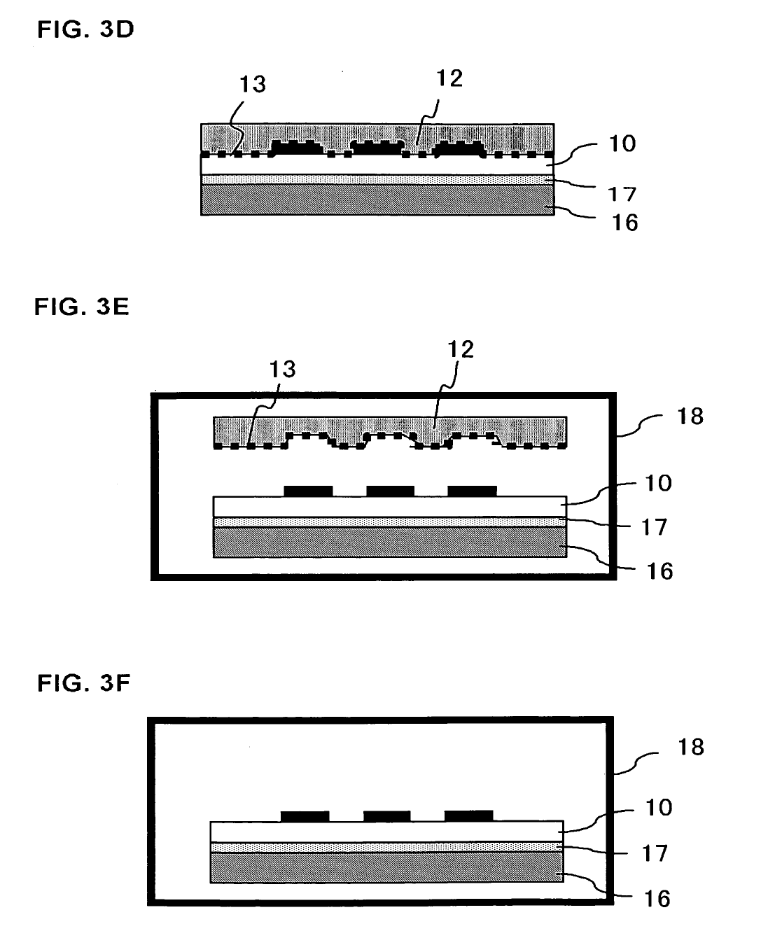

FIG. 2A to FIG. 2C and FIG. 3D to FIG. 3F are cross-sectional views, illustrating a procedure for manufacturing the thin film device 41 shown in FIG. 1.

In the above-described process step (i), the semiconductor elements 11 are formed on the substrate 10 (FIG. 2A). A thin film semiconductor element consisting of TFT, TFD, metal wirings and the like is formed on a substrate containing SiO₂ as a main component as the substrate 10, such as non alkali glass of a size having one side of equal to or larger than 100 mm, for example.

The TFT is obtained by forming a semiconductor thin film such as amorphous silicon or polysilicon on, for example, a glass substrate having a thickness of around 0.7 mm. The TFD is also obtained by forming a multiple-layered structure of metal/semiconductor (or insulating material)/metal on, for example, a glass substrate having a thickness of around 0.7 mm.

In the above-described process step (ii), a protective film 12 is provided on the semiconductor element layer via a cohesive agent 13 (FIG. 2B). In this occasion, for example, a sheet-shaped protective film 12 can be affixed thereon by using the cohesive agent 13. Available cohesive agent may include, for example, acrylic cohesive agent, urethane cohesive agent, Rubber cohesive agents and the like. The use of the cohesive agent leads to an easy stripping of the film 16 in the process step of (v). Materials of the cohesive agent 13 and the protective film 12 may be materials having resistance to the treatment process conducted in the step (iii) discussed later. The material is appropriately selected depending on the treatment process (iii), such as employing a material having better chemical resistance.

More specifically, available materials for the cohesive agent may include, for example, polyethylene terephthalate (PET), polyethylene naphthalate, polycarbonate, polybutylene terephthalate, polyether sulfone, polyolefin, polyetherimide, polyamide, polyamide imide, polyether ether ketone, polyarylate, siloxane resin, acrylic resin, epoxy resin, phenolic resin and the like. In addition, a polymer alloy of these polymers may be employed alone, or a multiple-layered member containing at least one of these polymer may be employed.

Here, a film-shaped or skin-shaped protective film 12 may be formed by coating a thermosetting resin via spin coating process on the surface of the substrate 10 having the semiconductor elements 11 provided thereon and heat-curing the coated resin. In this case, the cohesive agent 13 may be optionally employed.

In the above-described process step (iii), a portion of the substrate 10 is etched off from a back surface of the surface having the semiconductor elements 11 provided thereon (FIG. 2C). For example, when the substrate 10 is composed of a material containing SiO₂ as a main component, such as non alkali glass, the substrate is contacted with an etchant solution 14 containing hydrofluoric acid (hydrofluoric acid aqueous solution). Here, the etchant solution 14 may contain nitric acid, phosphoric acid, hydrochloric acid, sulfuric acid, ammonia and hydrogen peroxide. For example, the use of an etchant solution 14 containing hydrofluoric acid and nitric acid, hydrochloric acid, or sulfuric acid may further ensure the etching. In addition, the etching process may be conducted while providing ultrasonic vibration by an ultrasonic vibrator 15. While FIG. 2C illustrates that the whole element including the protective film 12 is immersed into the etchant solution 14 during the etching, it is sufficient that at least the etched surface of the substrate 10 contacts with the etchant solution 14.

Here, as described above, a material that is insoluble in the etchant solution 14 precipitates on the surface of the glass substrate 10 during the etching. For example, when a non alkali glass dedicated for the liquid crystal display is employed as the substrate 10, Water-insoluble material such as CaF₂ and the like precipitates on the surface of the substrate 10 in the etching thereof with hydrofluoric acid-containing solution, derived from Ca included in the glass. And, the generation of such precipitates might have inhibited the uniform etching.

To solve the problem, the present embodiment employs a configuration, in which the etching process is conducted while immersing the substrate 10 into the etchant solution 14 and providing ultrasonic vibration. Having such configuration, generation of the precipitates onto the etched surface of the substrate 10 is inhibited, such that the surface of the etched substrate 10 can be smoothed. In addition, the etching can be proceeded uniformly over the surface of the substrate 10. Thus, the generation of the warpage by the heat treatment conducted in the manufacturing process after the process step of (iv) can be inhibited. Thus, the thin film device 41 having better reliability can be stably manufactured, and therefore the production yield can be improved.

The condition of the etching may be suitably selected to provide the average roughness along a center line (Ra) of the surface of the etched substrate 10 of equal to or smaller than 3 μm, and preferably equal to or smaller than 1.5 μm. Having such configuration, the surface of the substrate 10 can be sufficiently smoothed that the warpage of the thin film device 41 can be surely prevented. In addition, suitable condition may also be selected so that Ra after the etching is equal to or larger than 1 nm, for example. Having such configuration, the adhesiveness with the film 16 can be improved since a slight unevenness can be created on the surface of substrate 10.

The etching process is continued until the thickness of the substrate 10 is within a range of from 20 nm to 200 μm, for example, and preferably within a range of from 100 nm to 100 μm. Having such configuration, the warpage generated by the heating can be inhibited while fully ensuring a flexibility of the substrate 10.

In addition, a frequency of ultrasonic wave may be set as equal to or higher than 10 kHz, for example, and preferably equal to or higher than 100 kHz. Having such condition, the adhesion or the deposition of the precipitates onto the etched surface of the substrate 10 can preferably be inhibited. Thus, even if the substrate 10 employed is larger, the surface thereof can be uniformly etched. Thus, fluctuation in the thickness of the etched substrate 10 can be reduced. Moreover, unevenness in the surface of the etched substrate 10 can be reduced to provide a uniform surface. Therefore, generation of the warpage can be reduced when the thin film device 41 is heated in the subsequent process.

In the above-described process step (iv), the film 16 is adhered onto the etched surface of the substrate 10 (FIG. 3D). The adhesion of the film 16 may be conducted by introducing an adhesive layer 17 between the substrate 10 and the film 16. In this case, thermosetting adhesive, photo-setting adhesive, cohesive agent and the like may be employed for the adhesive layer 17. Available cohesive agent may include, for example, acrylic cohesive agent, silicone cohesive agent, rubber cohesive agent and the like.

The adhesive layer 17 may be utilized by being applied on the etched surface of the substrate 10 or being applied on a film, and may be utilized by being applied on the surface of the film 16. For example, the coating process can be conducted by using, for example, a roll-to-roll type continuous coater, when the adhesive agent is applied onto the film 16, thereby manufacturing thereof with higher efficiency.

Moreover, the film 16 may be heated to a temperature that is equal to or higher than the softening point thereof to provide an adhesive-ability, and then may be adhered on the etched surface of the substrate 10. In this case, the film 16 can be heated to a temperature within a range of, for example, from a temperature that is the glass transition temperature thereof minus 30 degree C. to a temperature that is the glass transition temperature thereof plus 30 degree C. Excessively lower temperature may lead to insufficient softening of the film 16, providing insufficient adhesive-ability. On the other hand, excessively higher temperature may lead to a difficulty in maintaining the form of the film 16, causing a flow out or breaking during a processing.

The film 16 may also be formed by applying a melted resin on the etched surface of the substrate 10 via spin coating or the like and then cooling thereof to hardened the resin. The film 16 may also be formed by applying a solvent containing a resin dissolved therein on the etched surface of the substrate 10 and then volatilizing the solvent. In these cases, the adhesive layer 17 may be optionally introduced therebetween.

In addition, the film 16 may also be formed by applying a photo-setting liquid resin or a thermosetting liquid resin on the etched surface of the substrate 10 and then irradiating light or heating to cure the resin. When the film 16 is formed by curing the resin via irradiating light, the substrate 10, the adhesive layer 17, the protective film 12 and the cohesive agent 13 shall be made of materials that commonly have a transparency for the wave length of the irradiated light. This ensures the cure of the resin by irradiating light. Details of these methods will be described in second and third embodiments.

A material having a linear expansion coefficient at a temperature of from 30 degree C. to 100 degree C. of equal to or lower than 30 ppm/degree C., or a material having a glass transition temperature of equal to or higher than 200 degree C. may be employed for the film 16 and adhesive layer 17. Having such configuration, generation of the warpage by heating can be preferably inhibited, even if a heat treatment process is required in the adhesion process or process steps subsequent to the process step (v).

In the above-described process step (v), the cohesive agent 13 and the protective film 12 are stripped off from the surface of the substrate 10 (FIG. 3E). FIG. 3E illustrates a method for utilizing a thermally stripped-cohesive agent 13 and heating the element while containing the element within an oven 18. As such, the thin film device 41 is obtained. Since the configuration of satisfying the predetermined condition on Ra in the process step (iii) is employed, generation of the warpage can be inhibited if the heating process is conducted in this process. Here, in place of employing the oven 18, heating process for the element may be conducted by disposing the element on a hot plate.

The thin film device 41, which is a flexible electronic device, is obtained by the above described process. Here, there might be a case that the electrical characteristic or the reliability of the semiconductor element 11 be reduced by the processes employed in the above described process steps. In such a case, a subsequent heat treatment process of process step (vi) shall be conducted. This process can remove a process damage, to provide improved characteristics of the semiconductor element 11. Therefore, the reliability of the thin film device 41 can be improved.

In the above-mentioned process step (vi), a heat treatment process is made over the thin film device 41. The heating temperature may be equal to or higher than 70 degree C., and preferably equal to or higher than 100 degree C. Having such condition, moisture contained in the semiconductor element 11 may be surely evaporated, to obtain improved electrical characteristics.

While the heat treatment is optional in process step (iv) and/or process step (v), the heat treatment by this process (vi) is normally essential, as considering the characteristics of the thin film device 41. In this case, the heat treatment process is normally conducted by heating the thin film device 41 to a temperature of equal to or higher than 70 degree C. In the conventional technique, the warpage is occurred in the thin film device 41, due to the essential heat treatment. On the other hand, thin film device 41 is configured to satisfy the predetermined condition on Ra in the etched surface of the substrate 10 in the process step (iii). Further, the adhesive layer 17 and the film 16 may be composed of the above described materials. Thus, generation of the warpage in the heat treatment process can be inhibited, thereby providing an improved production yield of the thin film device 41.

Thin film device 41 obtained by the above described process has a configuration, in which height of the top of the lower surface of the film 16 from the horizontal level is, for example, equal to or less than 50 mm when the film 16 is placed on a horizontal plane, taking the film 16 down. As such, since the present embodiment involves etching the surface of the substrate 10 that will be the junction surface with the film 16 while providing ultrasonic vibration, the amount of warpage can be reduced. Thus, the thin film device 41 that promotes better manufacturing stability and higher production yield can be stably obtained. For example, when the thin film device 41, which is a transferred device, is utilized in the display unit as it is, the handling thereof and/or the production yield in adhering thereof onto other substrate can be improved since the warpage thereof is small.

Since the amount of warpage is larger in the device manufactured by the conventional method, crack and breakage may be occurred when a segmented device is cut out from the thin film device 41. On the contrary, since the flatness of the thin film device 41 according to the present embodiment is maintained even if a heat treatment is flexibly conducted, generation of the warpage in the small device cut off therefrom can also be prevented. Further, the production yield in the cutting process can be improved.

The thin film device 41 according to the present embodiment is flexible and thus presents smaller warpage. For example, the amount of warpage may be on the order of 15% or smaller of the maximum width in the surface of the thin film device 41. Thus, for example, the thickness of the glass substrate for the thin film silicon device formed on the insulating substrate such as the glass substrate may be considerably reduced, and thereafter a support such as a resin substrate having higher heat resistance is adhered thereon by using an adhesive layer having higher heat resistance, so that a flexible thin film silicon device exhibiting smaller warpage after the thermal processing can be manufactured.

Here, in the manufacturing process for the thin film device 41, an additional process for cleaning or activating the surface of etched side of the substrate 10 or the film 16 may be further provided, before the process (iv) for forming the junction between the film 16 and the substrate 10. Having such configuration, the adhesiveness between the substrate 10 and the film 16 is further improved, and thus considerably higher adhesion property can be obtained. Thus, peeling-off of the film 16 from the substrate 10 can be inhibited, thereby providing an improved manufacturing stability for the thin film device 41. Either one of the cleaning and the activation processes may be conducted, or both may be conducted.

Available cleaning methods may include, a method for conducting ultrasonic cleaning while a cleaning surface is immersed into a cleaning agent. The cleaning may be conducted over the etched surface of the substrate 10. Having such procedure, damage of the film 16 by a cleaning agent or moisture absorption into the film 16 can be avoided.

Available cleaning agents may include water such as pure water, ozone liquid and the like, acid such as hydrochloric acid, nitric acid and the like, alkali such as potassium hydroxide or tetramethylammonium hydroxide and the like, organic solvent such as 2-propanol, ethyl lactate and the like. Among these methods and agents, an ultrasonic cleaning process employing ozone liquid may be conducted to improve the cleaning effect, as compared to the case employing pure water. In addition, cost required for the safety countermeasures and the environmental countermeasures can be reduced as compared to the case employing other cleaning agents.

Available activation processes may include corona discharge treatment, short wavelength ultraviolet irradiation by a low-pressure mercury lamp, short wavelength ultraviolet irradiation by an excimer laser, oxygen plasma treatment in the vacuum, inverse sputter process in the vacuum and the like. Among these processes, corona discharge treatment, short wavelength ultraviolet irradiation by a low-pressure mercury lamp and short wavelength ultraviolet irradiation by an excimer laser are operable continually within an atmospheric environment, and thus these processes are preferably employed as a roll-to-roll process may be applicable for the film 16.

The activation process may be conducted over the etched surface of the substrate 10 or the surface of the film 16. When the activation process is conducted over the film 16, a dry process that is free of any liquid chemical solution may be employed. Having such configuration, damage of the film 16 by the liquid chemical solution or moisture absorption into the film 16 can be avoided.

### Second Embodiment

In method of first embodiment, a flush flow of an etchant solution may be supplied on the surface of the substrate 10 in the aforementioned process (iii), in stead of conducting an etching process while providing ultrasonic vibration. In addition, a stripping of the protective film 12 and an adhesion of the film 16 may be conducted by irradiating light. In this embodiment, a case of an electronic device having a TFT array and pixel electrodes will be illustrated.

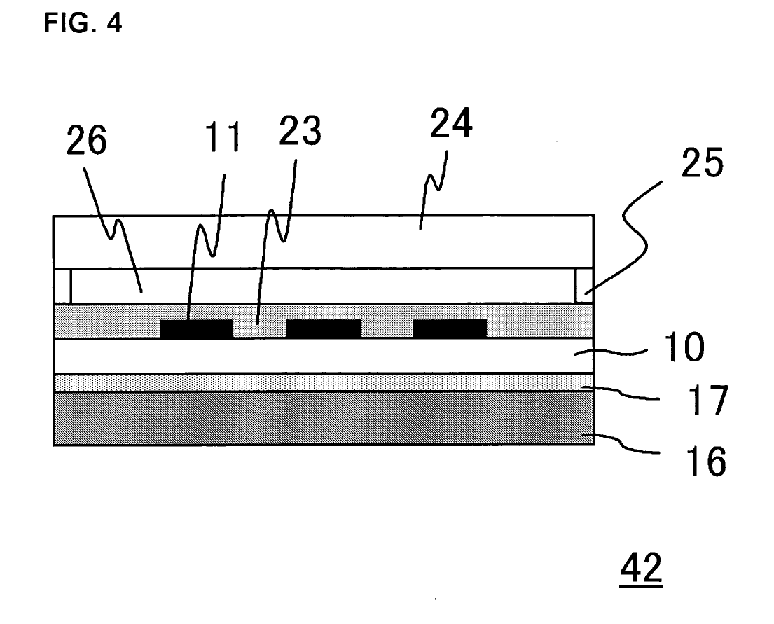

FIG. 4 is a cross-sectional view, schematically illustrating a configuration of a thin film device 42 according to the present embodiment. A basic configuration of the thin film device 42 is similar to the thin film device 41 shown in FIG. 1, and further comprises a multiple-layered configuration that is formed of a polyimide film 23, a liquid crystal 26, and a color filter substrate 24 which are layered in this order on the semiconductor element 11. The peripheral portions of the liquid crystal 26 are sealed by a sealing material 25. In addition, polysilicon TFT array including the pixel electrodes coupled to the TFTs' source electrode are provided as a semiconductor element 11.

In the thin film device 42, the substrate 10 and the film 16 are composed of a material that is transparent to a wave length of light irradiated in the manufacturing process. A transparent material may be suitably selected for such a transparent material from the materials listed in first embodiment.

In addition, the film 16 contains a photo-setting resin. More specifically, available photo-setting resin materials may include trimethylol propane trimethacrylate (TMPTMA), Trimethylol propane triacrylate (TMPTA), neopentyl glycol diacrylate, tetramethylol methane tetraacrylate, pentaerythritol triacrylate, pentaerythritol tetraacrylate and the like. The formation of film 16 by irradiating light can be easily conducted in the manufacturing procedure for the electronic device described below, by selecting a photo-setting material for the film 16.

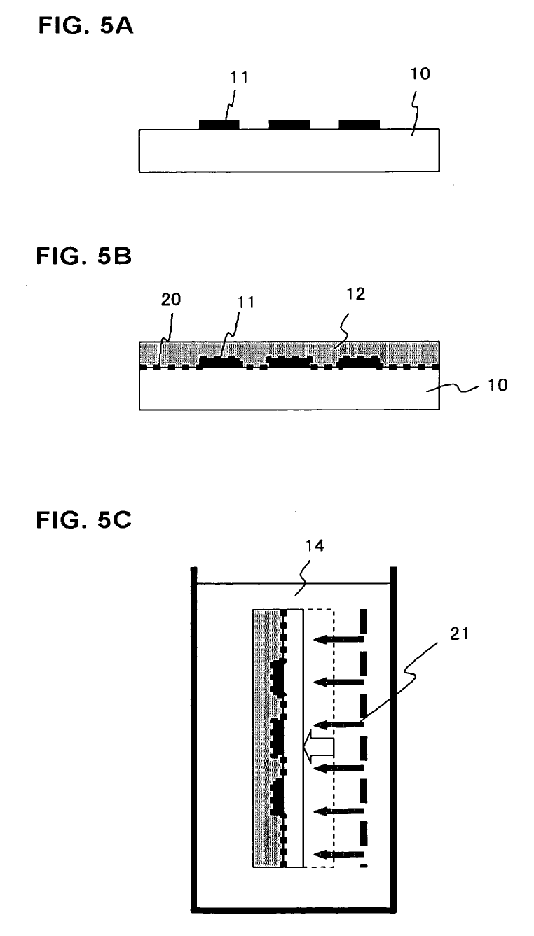

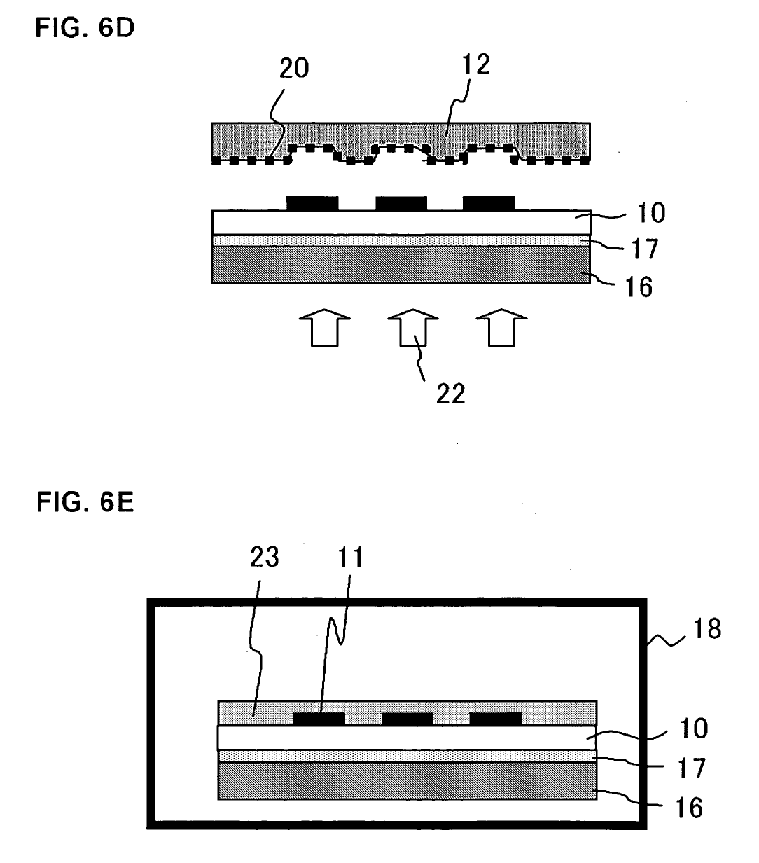

FIG. 5A to FIG. 5C and FIG. 6D to FIG. 6E are cross-sectional views, illustrating a manufacturing procedure for the thin film device 42 shown in FIG. 4. In the present embodiment, each procedure of the process steps (i) to (vi) described in first embodiment may also be utilized for the manufacture of the thin film device 42.

In the above-described process steps (i) and (ii), the method of first embodiment is utilized to form semiconductor elements 11 on the substrate 10 (FIG. 5A), and a protective film 12 that covers the semiconductor elements 11 are further provided (FIG. 5B). In the thin film device 42, a photo-stripping cohesive agent 20 is provided between the substrate 10 and the protective film 12.

An UV-curable cohesive agent, which is adhesive in an ordinary condition but is cured when ultraviolet irradiation is received to reduce the adhesiveness, is employed for the material for the photo-stripping cohesive agent 20. More specifically, such type of materials may include dipentaerythritol-monohydroxy penta-acrylate, dipentaerythritol hexa-acrylate and the like. Further, other photopolymetric compound may include acrylic acid derivatives such as 1,4-butylene glycol diacrylate, 1,6-hexanediol diacrylate, polyethylene glycol diacrylate, a commercially available oligoester acrylate and the like.

Available photoinitiator may include isopropyl benzoin ether, isobutyl benzoin ether, benzophenone, Michler's ketone (4,4′-Bis(dimethylamino)benzophenone), chloro thioxanthone, dodecyl thioxanthone, dimethyl thioxanthone, diethyl thioxanthone, acetophenone diethyl ketal, benzil dimethyl ketal, α-hydroxycyclohexyl phenyl ketone, 2-hydroxymethyl phenylpropane and the like, and a compound of these may be employed singlyj or in a combination of two or more kinds.

Next, in the above-described process step (iii), the substrate 10 is immersed within an etchant solution 14, and the etching process of the substrate 10 is carried out over the surface opposite to the surface having semiconductor elements 11 provided thereon (FIG. 5C). In this occasion, the etching process proceeds while creating a flush flow of the etchant solution 14 in the present embodiment. For example, when a non alkali glass dedicated for the liquid crystal display is employed as the substrate 10, water-insoluble material such as CaF₂ and the like precipitates on the surface of the substrate 10 in the etching thereof with hydrofluoric acid-containing solution, derived from Ca included in the glass. And, the generation of such precipitates may inhibit the uniform etching.

To solve the problem, the present embodiment employs a configuration, in which the etching process is conducted under a condition that provides a flush flow 21 of the etchant solution 14 striking on the surface of the substrate 10. Having such configuration, the etching process can be carried out while removing precipitates from the surface of the substrate 10 with a physical impact provided by the flush flow 21. Thus, deposition of a precipitate can be avoided, and Ra of the etched surface can be equal to or less than 3 μm. Thus, even if the substrate 10 having larger surface area is employed, the surface thereof can be uniformly etched along the plane direction of the substrate 10.

The etchant solution 14 may be suitably selected depending on the material of the substrate 10. For example, the materials exemplified in first embodiment may be employed.

Then, the above-described process steps (iv) and (v) are simultaneously conducted. The transparent film 16 is adhered onto the etched surface of the substrate 10 by employing adhesive to photo-setting adhesive agent as the adhesive layer 17 (FIG. 6D). For example, the film 16 is joined with the etched substrate 10 introducing the adhesive layer 17 therebetween by a laminator. Then, ultraviolet 22 is irradiated from the side of the film 16. Having such procedure, the adhesive layer 17 is cured, and the substrate 10 and the film 16 are adhered together.

In addition, as shown in FIG. 6D, stripping of the protective film 12 is simultaneously achieved by the ultraviolet irradiation. Thus, the wave length of light employed by the process for curing the adhesive layer 17 and the wave length of light employed by the process for stripping the photo-stripping cohesive agent 20 should be harmonized. Alternatively, respective lights employed by the respective processes may also be simultaneously irradiated.

Then, in the above-described process step (vi), a heat treatment is conducted over the obtained element by employing the method described in first embodiment (FIG. 6E). In this time, a polyimide film 23 for providing orientation to the liquid crystal 26 is simultaneously formed. A solution of polyimide is applied on the entire surface of the upper surface of the semiconductor element 11, and is then heated to a temperature within a range of from 150 degree C. to 250 degree C., so that the solvent can be removed to form a polyimide film 23.

Then, a color filter substrate 24 formed on a film is joined with the polyimide film 23 via sealing members 25. Further, liquid crystal 26 is injected into a gap between the color filter substrate 24 and the polyimide film 23, which is sealed by sealing members 25. The thin film device 42 shown in FIG. 4 is thus obtained by the above-described process.

In the present embodiment, since the level of unevenness in the etched surface of the substrate 10 is reduced similarly as in first embodiment, generation of the warpage in the heat treatment process can be inhibited. Thus, the production yield of the thin film device 42 can be improved.

In addition, in the present embodiment, the stripping process of the protective film 12 and the process for forming the junction of the film 16 can be simultaneously carried out by employing the photo-stripping cohesive agent 20 and the adhesive layer 17 composed of the photo-setting adhesive agent. Thus, the thin film device 42 exhibiting better production yield can be stably manufactured in a simple and easy method.

### Third Embodiment

While the above-described embodiments employ the removal of a portion of the substrate 10 by the etching in the process step (iii), polishing processes such as a grinding process employing a grinding stone can be employed, instead of the etching process. Mechanical polishing may be employed, and chemical polishing may also be employed. Moreover, chemical mechanical polishing (CMP) may be employed.

While the second embodiment employs the photo-stripping cohesive agent 20 and the photo-setting adhesive layer 17, a thermally stripping adhesive may be employed for the adhesion of the protective film 12, and a thermosetting adhesive may also be used for the adhesive layer 17 that provides adhesion of the film 16. Description will be made in reference to a case of a flexible silicon-on-insulator (SOI) device.

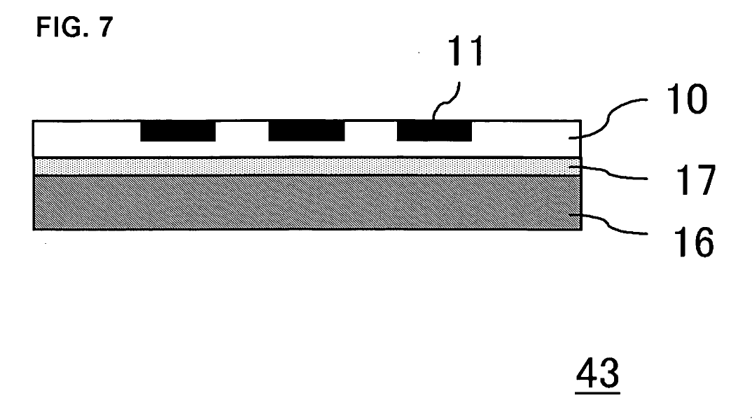

FIG. 7 is a cross-sectional view, schematically illustrating a configuration of a thin film device 43 according to the present embodiment. A basic configuration of the thin film device 43 is similar to the thin film device 41 shown in FIG. 1, and further comprises a configuration, in which semiconductor elements 11 are embedded within the substrate 10, and the surface of the substrate 10 is coplanar with the surface of the semiconductor element 11. In addition, the substrate 10 may be a SOI wafer, a silicon wafer substrate, a compound semiconductor substrate and the like. In addition, the semiconductor elements 11 are MOS transistor array, memory array and the like.

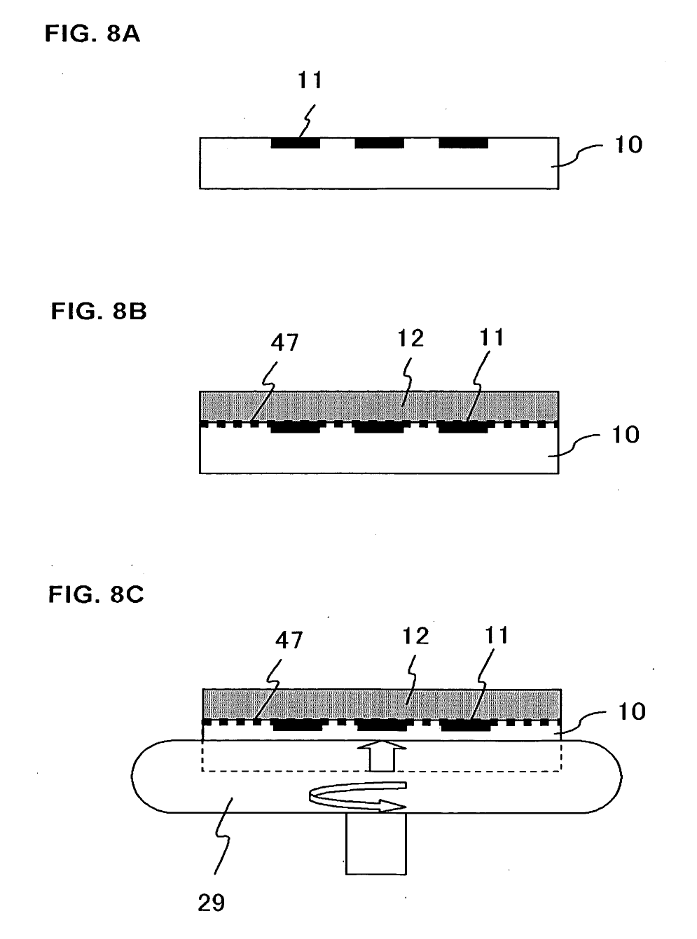

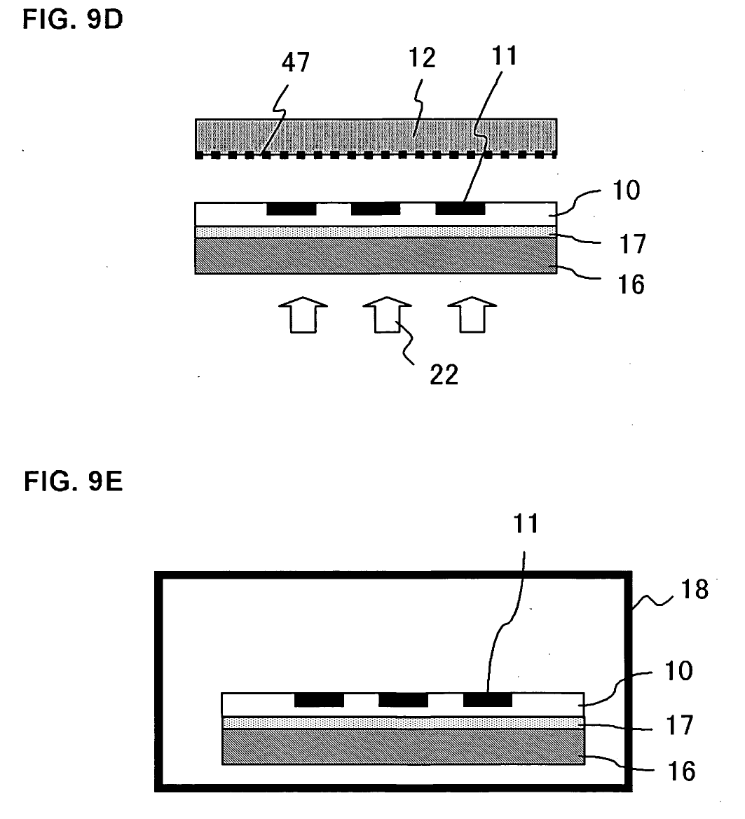

FIG. 8A to FIG. 8C and FIG. 9D to FIG. 9E are cross-sectional views, illustrating a manufacturing procedure for the thin film device 43 shown in FIG. 7. In the present embodiment, each procedure of the process steps (i) to (vi) described in first embodiment may also be utilized for the manufacture of the thin film device 43.

In the above-described process steps (i) and (ii), the semiconductor elements 11 are formed on the substrate 10 (FIG. 8A), and a protective film 12 that covers the semiconductor elements 11 are further provided (FIG. 8B). Here, manufacture of substrate 10 may be conducted by using a technology such as separation by implanted oxygen (SIMOX), epitaxial layer transfer (ELTRAN) and the like. In the thin film device 43, a thermally stripping cohesive agent 47 is provided between the substrate 10 and the protective film 12. For example, the thermally stripping cohesive agent 47 may be applied onto the surface of protective film 12, and then the surface of the substrate 10 having the semiconductor elements 11 provided therein may be tightly contacted to the applied surface of the protective film 12 and then adhered.

Available materials for the thermally stripping cohesive agent 47 may include a material that is capable of being foamed with a gas by heating. In such occasion, materials having relatively higher glass transition temperature such as polyimide, polyamide imide, polyetherimide, polyethersulfone, epoxy crosslinked resin, acrylic crosslinked resin and the like, may be employed for the substrate 10.

Next, in the above-described process step (iii), a process for grinding the substrate 10 is conducted from the back surface of the substrate 10 by using a grinding apparatus 29 (FIG. 8C). For example, process for grinding the substrate may be conducted until the thickness of the substrate 10 is reduced to a predetermined thickness, while water is supplied to the substrate 10 and an grinding stone of the grinding apparatus 29 to cool thereof off. After the grinding, an etching process or a polishing process may be appropriately conducted. Having such procedure, the etched surface of the substrate 10 can be further smoothed.

Then, the above-described process steps (iv) and (v) are carried out. The film 16 is adhered onto the etched surface of the substrate 10 thermosetting adhesive agent as an adhesive layer 17 (FIG. 9D). Available materials for the adhesive layer 17 may include a thermosetting resin having a curing shrinkage of equal to or less than 5%, and preferably equal to or less than 3%, may be employed. Having such configuration, generation of the warpage can be preferably inhibited, even if the thin film device 41 is heated.

The film 16 is joined with the etched substrate 10 via the adhesive layer 17 by a laminator. Then, the joined member is heated and is pressurized at a predetermined temperature and pressure, by using a heat press apparatus. Conditions of the heat press may be appropriately selected depending on the material. This process step provides a cure of the adhesive layer 17, and thus the substrate 10 and the film 16 are joined together. Further, since the adhesiveness of the thermally stripping cohesive agent 47 is reduced by the heat press, the protective film 12 can be stripped after unloading the elements from the heat press device.

Next, in the above-described process step (vi), a heat treatment is conducted over the obtained element by employing the method described in first embodiment (FIG. 9E). The thin film device 43 shown in FIG. 7 is thus obtained by the above-described procedure.

Since Ra of the etched surface can be equal to or less than 3 μm to reduce the unevenness thereof by conducting the mechanical grinding of the surface of the substrate 10 according to the present embodiment, generation of the warpage due to the heat treatment process can be inhibited. Therefore, the production yield of the thin film device 43 can be improved. Further, in the present embodiment, the stripping process of the protective film 12 and the process for forming the junction of the film 16 can be simultaneously carried out by employing the thermally stripping cohesive agent 47 and the adhesive layer 17 composed of thermosetting adhesive agent. Thus, the thin film device 43 exhibiting better production yield can be stably manufactured in a simple and easy method.

The present invention has been described on the basis of the preferred embodiment. It should be understood by a person having ordinary skills in the art that the present embodiment is disclosed for an illustration only, and the various changes thereof are available and are within the scope of the present invention.

For example, the electronic device obtained by the above-mentioned embodiments can be cut off to obtain segmented devices chip having a predetermined dimension via dicing process or the like. Since the warpage of the electronic device is prevented, generation of warpage in each of the obtained small devices is also prevented, thereby providing an improved production yield.

Further by method described in the above-mentioned embodiment, thin film devices such as the thin film transistor-transferred devices can also be stably obtained. This includes a flexible liquid crystal display employing semiconductor elements such as thin film transistor for a drive circuit of liquid crystal element of each pixel, flexible thin display such as organic EL display or the like. In particular, peripheral circuits such as driver circuit for scanning line or signal line, digital-analog converting circuit, memory circuit and the like may be constructed as forms of thin film transistors, such that a high performance-flexible display integrated with the peripheral circuits can be achieved.

Further, for example, the electronic device of the present invention can be utilized in place of the electronic devices currently manufactured from silicon wafer such as IC card, IC chip for IC tag and the like. Since a glass substrate having larger surface area than a silicon wafer can be employed for the substrate 10 that is a first base member in this case, available number of IC chips cut out from one piece of the substrate 10 is infinitely increased, thereby reducing the production cost. In addition, the film 16 is not necessarily transparent in this case, and metallic films such as copper foil or the like is available.

Further, the device may also be utilized for solar cell devices formed of amorphous silicon thin film, polycrystalline silicon thin film or the like. Pattern of the solar cell device formed on a hard substrate such as glass substrate is transferred on a flexible film by employing the transfer process as utilized in the present invention. Thereafter, a heat treatment at a temperature on the order of 100 degree C. is conducted in order to improve the process efficiency, so that a solar cell device having higher performances, being flat and flexible can be achieve. Such solar cell device involves better utility, since the solar cell device can be disposed on an arbitrary curved surface as well as on a flat surface.

### EXAMPLES

While details of the present invention will be described specifically below by way of illustrating various examples, it is not intended to limit the scope of the present invention thereto.

### Example 1

In the present example, variable methods for reducing the thickness of the substrate were examined in the aforementioned process step (iii) to conduct comparative evaluations for the creation of the deposits on the surface and the generation of the warpage by heating.

A non alkali glass plate having a size of 30 cm×40 cm was employed for the substrate. The initial thickness of the glass was 700 μm. The etching process was continued under respective conditions described below until the thickness of the substrate is reduced to 80 μm. Here, the mixing ratio by weight of the etchant solution employed in the following (A) and (B) was, hydrofluoric acid:hydrochloric acid:water=1:1:3. Further, the respective obtained substrates were heated at a temperature of 120 degree C. for 60 minutes, and then amounts of the warpage were measured. Here, an amount of warpage was defined as a difference in the height between the lowest portion and the highest portion of glass substrate in any region of the glass substrate when a normal vector extending from the surface of the glass substrate toward a surface opposite to the etched surface is oriented toward a horizontal plane or is oriented toward above from the horizontal plane when the etched glass substrate is placed on a flat surface without exerting any external force disposed on a surface.
(A) simple etching;
(B) etching with mega sonic (MS) vibration; and
(C) etching with flush flow.
   Here, in the above-described (C), the flush flow was generated by adjusting frequency for the inverter operation of the pump.

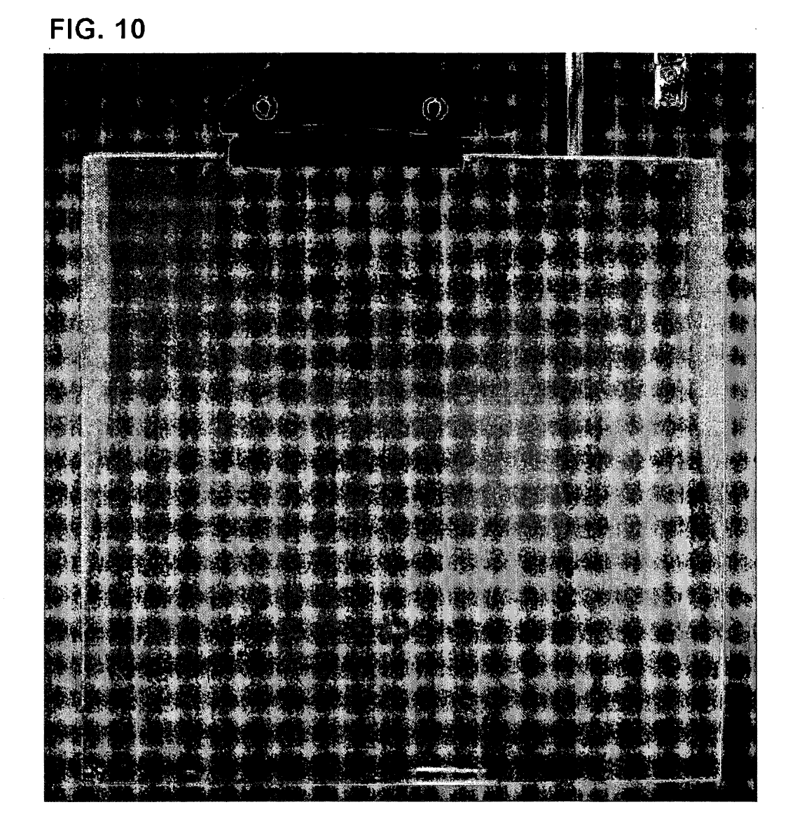

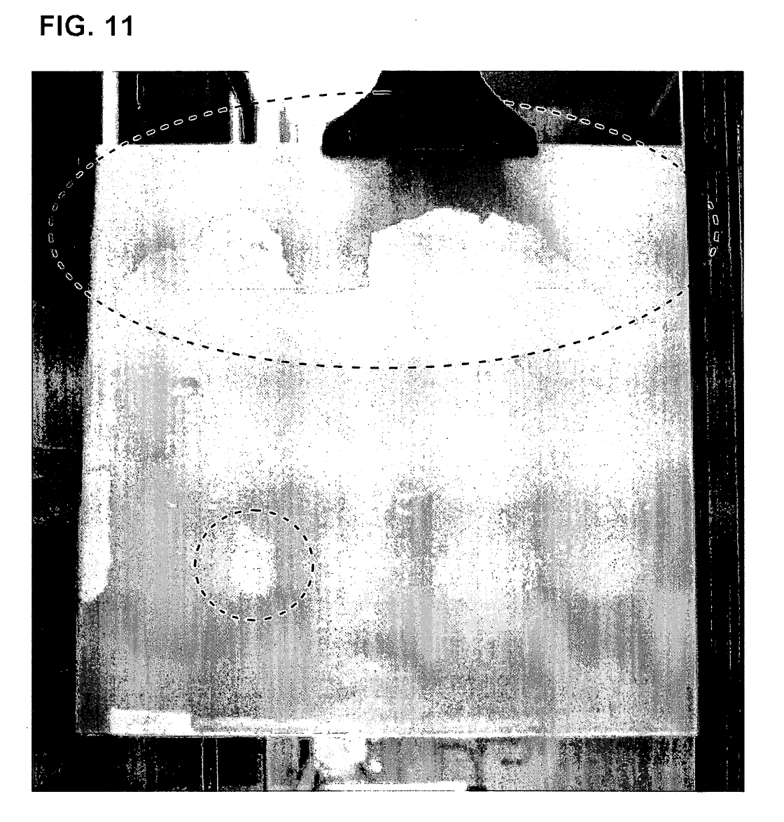

FIG. 10 is a photograph, showing a surface of a substrate, which was etched via process (B). FIG. 11 is a photograph, showing a surface of a substrate, which was etched via process (A). As can be seen from the photographs of FIG. 10 and FIG. 11, no deposition of precipitate was not observed on the surface of the substrate of (B), which was etched in the flush flow. On the contrary, depositions of precipitates were found on the surface of the substrate of (A), which was etched without generating a flush flow, and the precipitates covered the surface of the substrate. Although it is not illustrated here, no deposition of precipitate was observed on the surface of the substrate of (C), which was mechanically ground, similarly on the substrate of (B).

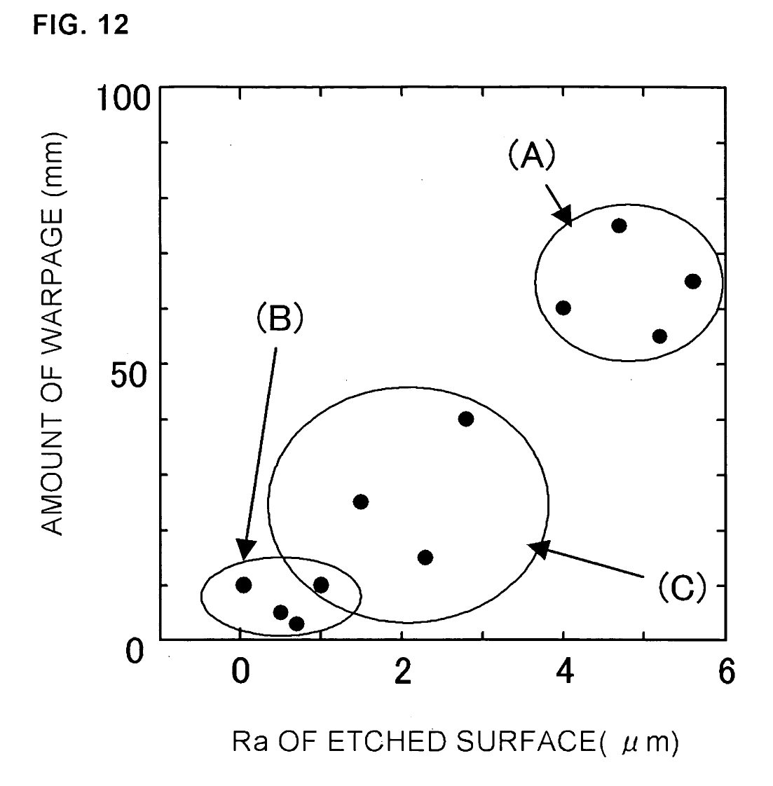

FIG. 12 is a graph, showing a relationship of Ra in the surface of the substrate obtained by these methods with the amount of warpage after the heating process. As for FIG. 12, a profiler (P-15, commercially available from KLATENCOR) was employed in the measurement of Ra, and the measurements were conducted in a region at an arbitrary location on the etched surface having a length of 5 mm.

As can be seen from FIG. 12, there is a positive correlation between Ra in the substrate surface and amount of warpage, and smaller Ra provides reduced amount of warpage after the heating process. Further, it was found that Ra was able to be reduced to 3 μm or smaller and amount of warpage can be reduced to 50 mm or smaller by employing the flush flow or MS. Further, reduced the amount of warpage was able to be further reduced by providing Ra of 1.5 μm or smaller, and the amount of warpage was 10 mm or smaller.

### Example 2

In the present example, a flexible integrated circuit device comprising a polysilicon TFT array formed therein as semiconductor element 11 was manufactured in the thin film device 41 shown in FIG. 1. The manufacture of the thin film device 41 was conducted by the method described in reference to FIGS. 2A to 2C and FIGS. 3D to 3F.

A non alkali glass plate having a size of 300 mm×350 mm and a thickness of 0.7 mm was employed for the substrate 10. The polysilicon TFT array was manufactured by the following method.

First, a SiO₂ film was deposited to a thickness of 200 nm on the substrate 10 via a plasma CVD. Thereafter, amorphous silicon was deposited to a thickness of 50 nm via a thermal CVD. Subsequently, the amorphous silicon film was reformed to a polysilicon film via a laser beam annealing. Then, the polysilicon film was patterned to a desired geometry, and thereafter, SiO₂ film was deposited as a gate insulating film to a thickness of 100 nm via a plasma CVD. Then, a gate electrode was formed, and thereafter, phosphorus or boron was doped into a predetermined region via an ion doping process to form a region acquiring n-type conductivity and a region acquiring p-type conductivity. Subsequently, a SiO₂ film was deposited as an interlayer insulating film to a thickness of 300 nm to form a contact hole. Thereafter, a source drain electrode and an interconnect composed of aluminum were formed. A n-channel TFT and a p-channel TFT were formed through the above-mentioned process.

These TFTs were coupled via a desired interconnect pattern to form complementary metal oxide semiconductor (CMOS) inverter basic circuits, and suitably selected basic circuits from these circuits were combined to form various types of digital-analog circuits, memory circuits and the like to form a LSI circuit.

Subsequently, a protective film 12 was adhered onto the polysilicon TFT array by using the method of first embodiment. In the present example, a film composed of PET as a base member and having a thickness of 100 μm was employed for the protective film 12. A cohesive agent 13 was applied on the protective film 12, and the protective film 12 was adhered to the polysilicon TFT array via the cohesive agent 13. A thermally stripping cohesive agent was employed in the present example.

Next, the substrate 10 having the protective film 12 adhered thereon was immersed within an etchant solution 14 composed of hydrofluoric acid, hydrochloric acid and water, and the substrate 10 was etched from the back surface of the element formation surface. The mixing ratio by weight of the etchant solution 14 was, hydrofluoric acid:hydrochloric acid:water=1:1:3. In the present example, the etching process was continued while precipitates were continuously removed from the surface of the substrate 10 by providing ultrasonic vibration of 1 MHz to the etchant solution 14 by using an ultrasonic vibrator 15. As a result, depositions of precipitates were inhibited, thereby conducting uniform etching.

An etch rate in the case of using the above-described solution was around 3.0 μm/min., and under such etch rate, the etching process was continued until the average of the thicknesses in the substrate 10 was reduced to 100 μm. Thickness distribution in the surface of the substrate 10 was measured, and the results were that: 90 μm for the thinnest portion and 110 μm for the thickest portion, and therefore it was found that practical etching uniformity was obtained by conducting the etching process while providing ultrasonic vibration. Concerning the unevenness in the etched surface, Ra was on the order of 0.2 μm.

Then, the film 16 was adhered onto the etched surface of the substrate 10 via an adhesive layer 17. An acrylic resin containing a glass filler having an average particle diameter of 5 μm was employed for the film 16. Thickness of the film 16 was 150 μm. Further, linear expansion coefficient of the film 16 was 27 ppm/degree C. Optical transmittance at a wave length of 365 nm was 42%. Further, light transmittances at wave lengths of 400 nm and 550 nm were 81% and 84%, respectively. Phase difference at a wave length of 550 nm was 0.5 nm. Glass transition temperature was 245 degree C.

An adhesive agent that would be the adhesive layer 17 was applied in advance on the film 16. Acrylic photo-setting adhesive agent was employed for the material of the adhesive layer. Light transmittances of the adhesive layer 17 at wave lengths of 400 nm and 550 nm were 88% and 90%, respectively. Further, phase difference at a wave length of 550 nm was 0.1 nm.

The etched semiconductor elements 11 and the film 16 having the adhesive layer 17 were joined with a laminator, and thereafter, ultraviolet was irradiated from the side of the film 16 to cure the adhesive layer 17, and thus the substrate 10 and the film 16 were adhered and fixed together. Glass transition temperature of the adhesive layer 17 was 220 degree C., and the thickness thereof was 5 μm.

Further, unevenness of the etched surface after the etching in the process step (iii) was on the order of 0.2 μm. This leads to an increase of the adhesive effective area as compared with the case of completely flat surface, thereby providing further improved adhesion property.

Thereafter, the elements were disposed within an oven 18 and then a heat treatment process was conducted to strip the protective film 12. When the thermal processing was carried out for two minutes within the oven at a temperature of 100 degree C., the cohesive agent 13 was foamed, and thus the protective film 12 was completely stripped.

A heat treatment process of process step (vi) was additionally conducted in the flexible TFT device obtained by the above procedure, in order to provide an improved electrical characteristics of the TFT. The thin film device 41 was rinsed with water, and then was thermally processed in the oven 18 at a temperature of 70 degree C. The warpage of the thin film device 41 was small even in such additional heat treatment, and thus the flexible TFT device having improved electrical characteristics was able to be manufactured.

When such flexible TFT device was placed on a flat plane without giving any external force, the highest point in the device was lower, which was 10 mm from the surface of the flat plane. Further, since the warpage is small, a segmented chip of an arbitrary geometry was able to be easily cut out from the flexible TFT device. Small flexible TFT devices having one side of 20 mm were obtained by cutting. Since the amount of warpage was larger in prior art, various problems were caused such as cracking during the cutting or breaking of the device. In the present example, the flexible TFT device, which was flexible and was smooth after the heat treatment was able to be achieved.

### Example 3

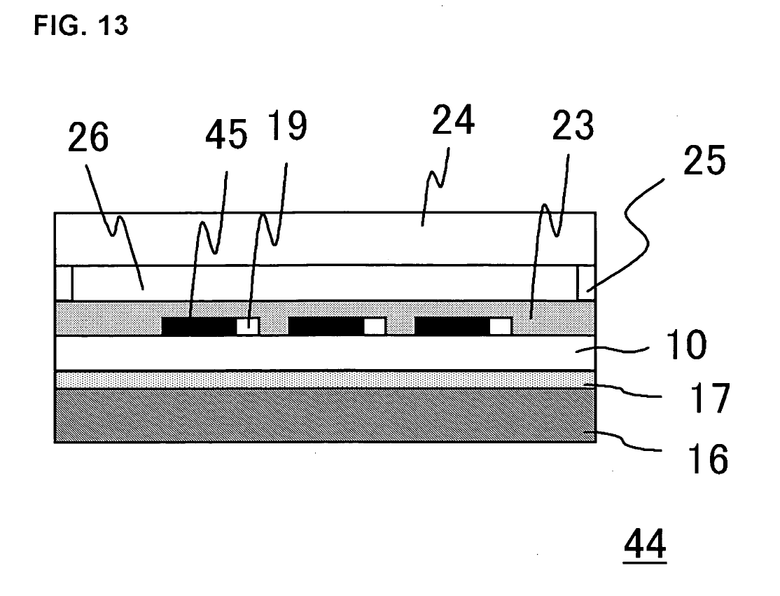

In the present example, a liquid crystal display employing a polysilicon TFT as a driver element for liquid crystal element of each pixel was manufactured by employing the method described in second embodiment (FIG. 5 and FIG. 6). FIG. 13 is a diagram, illustrating a liquid crystal display 44 according to the present example.

A polysilicon TFT array 45 and pixel electrodes 19 were formed on the substrate 10 of non alkali glass. Size of the glass substrate was 400 mm×500 mm, and thickness was 0.7 mm. Similar manufacturing method as used in example 2 was employed for manufacturing the polysilicon TFT array. The pixel electrodes were formed so as to be coupled to source electrodes of respective polysilicon TFTs formed in matrix-shaped. Further, similarly as in example 2, peripheral driver circuits were simultaneously formed on the substrate 10 from n channel TFT and p channel TFT.

Subsequently, a protective film 12 was adhered onto the polysilicon TFT array 45. In the present example, a photo-stripping cohesive agent 20 was applied on the surface of the protective film 12, and the protective film 12 was adhered onto the polysilicon TFT array 45 via this cohesive agent.

Then, the substrate 10 having the protective film 12 adhered thereon was immersed within an etchant solution 14 composed of hydrofluoric acid, hydrochloric acid and water, and the substrate 10 was etched from the back surface side thereof. The mixing ratio by weight of the etchant solution 14 was, hydrofluoric acid:hydrochloric acid:water=1:1:3. Further, the etching process was continued while a flush flow 21 of the etchant solution 14 struck on the surface of the substrate 10 to continuously remove precipitates from the surface of the substrate 10 with a physical impact provided therefrom.

As a result, the deposition of the precipitate was inhibited to provide an uniform etching. An etching rate with the etchant solution 14 having the above-described composition was on the order of 3.5 μm/min., and the etching process was continued until an average thickness of the substrate 10 was reduced to 80 μm. Thickness distribution in the surface of the substrate 10 was measured, and the results were that: 70 μm for the thinnest portion and 90 μm for the thickest portion. Therefore, it was found that practical etching uniformity was obtained by conducting the etching process while providing the flush flow to the surface of the substrate 10. The unevenness in the surface of the etched substrate 10 was on the order of 2.0 μm.

Then, a film 16 was adhered on the etched surface via an adhesive layer 17. In the present example, an acrylic resin containing a glass filler having an average particle diameter of 1 μm was employed for the film 16. Thickness of the film 16 was 150 μm. Further, linear expansion coefficient of the film 16 was 28 ppm/degree C. Light transmittances at wave lengths of 400 nm and 550 nm were 83% and 87%, respectively. Phase difference at a wave length of 550 nm was 0.5 nm. Glass transition temperature was 247 degree C.

An adhesive agent for forming the adhesive layer 17 was applied on the surface of the film 16 in advance. A mixture of pentaerythritol triacrylate, pentaerythritol tetra acrylate and epoxy acrylate, all of which are acrylic photo-setting adhesive agents for forming the adhesive layer 17, was employed. Light transmittances of the adhesive layer itself at wave lengths of 400 nm and 550 nm were 88% and 90%, respectively. Phase difference at a wave length of 550 nm was 0.2 nm.

The etched substrate 10 was joined with the film 16 having the adhesive layer 17 thereon by a laminator. Then, ultraviolet 22 having a wavelength of 365 nm was irradiated from the side of the film 16 to cure the adhesive layer 17, and thus the substrate 10 and the film 16 were adhered and fixed together. Glass transition temperature of the adhesive layer 17 was 220 degree C., and the thickness thereof was 10 μm. Further, unevenness of the etched surface after the etching in the process step (iii) was on the order of 2.0 μm, and this leads to an increase of the adhesive effective area as compared with the case of example 1, thereby providing further improved adhesion property.

In the present example, a photo-stripping cohesive agent 20 was employed for adhering the protective film 12. Thus, in the operation of irradiating ultraviolet in the process for adhering the film 16, the protective film 12 was also able to be stripped simultaneously with adhering the film 16.

Then, the obtained liquid crystal display 44 was washed with water for obtaining better electrical characteristics of TFT. Then, a heat treatment at a temperature of 70 degree C. was conducted within the oven 18. A polyimide film 23 is applied on the surface of the substrate 10 having the pixel electrodes 19 and the polysilicon TFT array 45 provided thereon, and then thermally processed at a temperature of 180 degree C. In this occasion, substantially no warpage was occurred in liquid crystal display 44.

Then, a color filter substrate 24 formed on the film is prepared separately from the flexible TFT substrate, and these two substrates were adhered via a sealing member 25, and thereafter, liquid crystal 26, is injected therein to manufacture a flexible liquid crystal display exhibiting smaller warpage and having the polysilicon TFTs as driver elements for the liquid crystal element of each pixel.

### Example 4

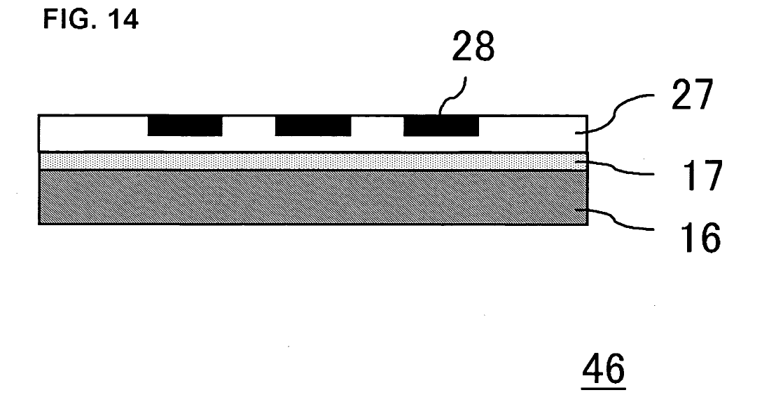

In the present example, a MOS transistor array or a memory array were formed on a SOI wafer substrate, and thereafter the substrate was ground from the back surface of the substrate to reduce the thickness thereof, and then a film is adhered thereon to form a flexible SOI device. FIG. 14 is a cross-sectional view, schematically illustrating a configuration of a SOI device 46 according to the present example. The manufacture of the SOI device 46 was conducted by using the method described above in reference to FIGS. 8A to 8C and FIGS. 9D to 9E.

A MOS transistor array 28 was formed on a 8-inch SOI wafer 27. Then, a thermally stripping cohesive agent 47 was applied onto the surface of the protective film 12, and the protective film 12 was adhered onto an array-forming surface of the SOI wafer 27 via the thermally stripping cohesive agent 47. Polyethylene terephthalate (PET) was used for a base member of the protective film 12.

Then, a process for grinding the SOI wafer 27 is conducted from the back surface thereof by using a grinding apparatus 29 to form a thin SOI wafer. Process for grinding the substrate may be conducted until the thickness of the remained wafer was reduced to 80 μm, while a water is supplied to the SOI wafer 27 and grinding stone. The unevenness in the surface of the polished substrate was on the order of 0.2 μm.

Thereafter, the film 16 was adhered on the ground surface of the SOI wafer 27 via the adhesive layer 17. In the present example, a copper foil film having a thickness of 50 μm was employed for the film 16. Further, a composition containing bisphenol A based epoxy resin, which is an epoxy-based thermosetting adhesive agent, and naphthalene based epoxy resin as materials of the adhesive layer 17, was employed. A copper foil film and a thin SOI wafer were adhered, and thereafter, the obtained member was heated at a temperature of 150 degree C. for 90 minutes while pressing at a pressure of 0.1 MPa by using a heat press device to cure the adhesive layer 17, and thus the thin SOI wafer and the copper foil film were adhered and fixed together. Since the adhesive strength of the thermally stripping cohesive agent was correspondingly reduced in this time, the protective film 12 was stripped after unloading from the heat press device.

Finally, in order to obtain better electrical characteristics of MOS transistor array 28, the SOI device 46 was rinsed with water, and then was thermally processed in the oven 18 at a temperature of 120 degree C. The warpage of the SOI device 46 was small in such additional heat treatment, and thus the flexible SOI device having improved electrical characteristics was able to be manufactured. When such SOI device 46 was placed on a flat plane without giving any external force, the highest point in the device was lower, which was 10 mm from the surface of the flat plane. Further, since the warpage is small, dicing of the SOI device 46 was easily conducted to cut out a small device.

### Example 5

In the similar approaches as in example 4, devices having different materials of the film 16 were manufactured. Polyimide film having a thickness of 75 μm was employed, in place of the copper foil film having a thickness of 50 μm. Linear expansion coefficient of the polyimide film was 5 ppm/degree C., and light transmittances thereof at wave lengths of 400 nm and 550 nm were 18% and 64%, respectively, phase difference thereof at a wave length of 550 nm was 24 nm, and glass transition temperature thereof was 275 degree C.

Then, similarly as in example 4, the obtained flexible SOI device exhibited smaller warpage, and had excellent electrical characteristics. When such SOI device 46 was placed on a flat plane without giving any external force, the highest point in the device was 10 mm from the surface of the flat plane, and exhibited smaller warpage. Further, since the warpage is smaller, dicing of the SOI device 46 was easily conducted to cut out a small device.

Here, in the above described present example, a predetermined cleaning process or activating process can be conducted for the adhesive surface, before adhering film 16.

It is apparent that the present invention is not limited to the above embodiment, that may be modified and changed without departing from the scope and spirit of the invention.

1. An electronic device, comprising:
a first base member;
a semiconductor element, being provided on an element formation surface of said first base member and having a thickness of equal to or smaller than 200 μm; and
a second base member, being provided on a back surface of said first base member,
wherein an average roughness along a center line (Ra) of said back surface of said first base member is equal to or smaller than 3 μm.

2. The electronic device according to claim 1, wherein an adhesion layer is provided between said second base member and said first base member.

3. The electronic device according to claim 2, wherein said adhesion layer comprises an ultraviolet (UV) curable resin.

4. The electronic device according to claim 2, wherein said adhesion layer comprises a thermosetting resin, and curing shrinkage of said adhesion layer is equal to or lower than 5%.

5. The electronic device according to claim 1, wherein said second base member contains a crosslinked resin material and an inorganic material.

6. The electronic device according to claim 1, wherein said second base member comprises a material that is transparent to UV.

7. The electronic device according to claim 1, wherein said second base member contains one or more resin(s) selected from a group consisting of polyimide, polyamide and polyamide imide.

8. The electronic device according to claim 7, wherein said second base member contains either aliphatic acrylate or alicyclic epoxy resin.

9. The electronic device according to claim 1, wherein a linear expansion coefficient of said second base member at a temperature of from 30 degree C. to 100 degree C. is equal to or lower than 30 ppm/degree C.

10. The electronic device according to claim 1, wherein said first base member is a glass.

11. The electronic device according to claim 1, wherein said back surface of said first base member is an etched surface.

12. The electronic device according to claim 1, wherein said back surface of said first base member is a polished surface.

13. The electronic device according to claim 1, wherein a geometry of said second base member is a film-shaped geometry.

14. The electronic device according to claim 1, wherein said second base member is a flexible substrate.

15. The electronic device according to claim 1, wherein said semiconductor device is manufactured by conducting a heat treatment process over a multiple-layered structure at a temperature of not lower than 70 degree C., said multiple-layered structure comprising at least said second base member and said semiconductor element;
wherein said electronic device has an arbitrary geometry that is capable of masking a square having one side of 100 mm and the thickness of said semiconductor element is equal to or smaller than 200 μm,
wherein said electronic device has a spatial relationship, in which, when said electronic device is placed on a flat surface without exerting any external force, a normal vector is oriented toward a horizontal plane or is oriented toward above from the horizontal plane, said normal vector extending from entire regions of said semiconductor element to a direction opposite to the direction toward said second base member, and
wherein the highest point of said electronic device is equal to or lower than 50 mm high from the surface of said flat surface.

16. The electronic device, which is manufactured by cutting a small chip of an arbitrary geometry out from the electronic device according to claim 15.

17. The electronic device according to claim 15, wherein said semiconductor element is a thin film silicon transistor element or a thin film diode element, which is formed on a film consisting essentially of silicon oxide or silicon nitride.

18. The electronic device according to claim 17, wherein a thickness of said film consisting essentially of silicon oxide or silicon nitride is within a range of from 20 nm to 200 μm.

19. The electronic device according to claim 17, wherein an average roughness along a center line (Ra) of a surface of said film that faces to said second base member is within a range of from 1 nm to 3 μm, said film consisting essentially of silicon oxide or silicon nitride.

20. The electronic device according to claim 17, wherein said thin film silicon transistor element or said thin film diode element is employed as an element for a display unit.

21. The electronic device according to claim 15, wherein said semiconductor element is formed on a silicon wafer, a compound semiconductor wafer or a silicon on insulator (SOI) wafer.

22. A method for manufacturing an electronic device, comprising:
forming a semiconductor element on a first base member;
removing a portion of said first base member from a surface opposite to a surface having said semiconductor element provided thereon to reduce the thickness of said first base member;
adhering the second base member to the surface of said first base member opposite to the surface having said semiconductor element provided thereon to obtain the electronic device; and
heating said electronic device after said adhering the second base member,
wherein said removing a portion of said first base member to reduce the thickness thereof includes providing an average roughness along a center line (Ra) of the surface of said first base member opposite to the surface having said semiconductor element provided thereon to equal to or lower than 3 μm.

23. The method according to claim 22, wherein said heating the electronic device includes heating said electronic device to a temperature of equal to or higher than 70 degree C.

24. The method according to claim 22, wherein said removing a portion of said first base member to reduce the thickness thereof includes providing ultrasonic vibration to an etchant while maintaining a condition of said etchant contacting with said first base member.

25. The method according to claim 22, wherein said removing a portion of said first base member to reduce the thickness thereof includes contacting the surface of said first base member opposite to the surface having said semiconductor element provided thereon with a flush flow of said etchant.

26. The method according to claim 24, wherein said first base member is a glass, and said etchant contains hydrofluoric acid.

27. The method according to claim 24, wherein said removing a portion of said first base member to reduce the thickness thereof includes polishing said first base member.

28. The method according to claim 22, wherein said adhering the second base member includes introducing an adhesion layer between said first base member and said second base member.

29. The method according to claim 22, further comprising cleaning said surface of said first base member opposite to the surface having said semiconductor element provided thereon or the surface of said second base member, before said adhering the second base member.

30. The method according to claim 22, further comprising activating said surface of said first base member opposite to the surface having said semiconductor element provided thereon or the surface of said second base member, before said adhering the second base member.

31. The method according to claim 22, further comprising providing a protective layer on said semiconductor element, after said forming the semiconductor element and before said removing a portion of said first base member to reduce the thickness thereof.

32. The method according to claim 31, further comprising removing said protective layer after said removing a portion of said first base member to reduce the thickness thereof.
